(19) United States
(12) Patent Application Publication
(10) Pub. No.: US 2025/0309047 A1
(43) Pub. Date: Oct. 2, 2025

(54) LIQUID AND AIR COMBO COOLING FOR MULTI-CHIP MODULES

(71) Applicant: Adeia Semiconductor Bonding Technologies Inc., San Jose, CA (US)

(72) Inventors: Ron Zhang, Sunnyvale, CA (US); Gaius Gillman Fountain, Jr., Youngsville, NC (US); Belgacem Haba, Saratoga, CA (US); Rajesh Katkar, Milpitas, CA (US); Laura Mirkarimi, Sunol, CA (US)

(21) Appl. No.: 18/807,160

(22) Filed: Aug. 16, 2024

Related U.S. Application Data
(60) Provisional application No. 63/571,952, filed on Mar. 29, 2024.
(60) Provisional application No. 63/651,762, filed on May 24, 2024.

(51) Int. Cl. H01L 23/467; H01L 21/48; H01L 23/00; H01L 23/367; H01L 23/42; H01L 25/065

(52) U.S. Cl. CPC H01L 23/467; H01L 21/4882; H01L 23/42; H01L 24/08; H01L 25/0652; H01L 23/3672; H01L 2224/08245; H01L 2225/06568

(57) ABSTRACT

In some implementations, a cooling apparatus may include an integrated cooling assembly comprising a first die and a cold plate having first and second portions, the first portion being attached to a backside of the first die, the second portion being spaced apart from the backside of the first die to define at least one fluid channel arranged for a liquid coolant between the second portion and the backside of the first die. The cooling apparatus further includes a plurality of second dies communicatively coupled to the first die and one or more heat sinks attached to at least one second die of the plurality of second dies. The cold plate is thermally decoupled from the one or more heat sinks.

### CROSS-REFERENCE TO RELATED APPLICATION

This application claims the benefit of U.S. Provisional Patent Application Nos. 63/571,952, filed Mar. 29, 2024, and 63/651,762, filed May 24, 2024, each of which is incorporated by reference herein in its respective entirety.

### TECHNICAL FIELD

The present disclosure relates to advanced packaging for microelectronic devices, and in particular, cooling systems for device packages and methods of manufacturing the same.

### BACKGROUND

Energy consumption poses a critical challenge for the future of large-scale computing as the world's computing energy requirements are rising at a rate that most would consider unsustainable. Some models predict that the information, communication, and technology (ICT) ecosystem could exceed 20% of global electricity use by 2030, with direct electrical consumption by large-scale computing centers accounting for more than one-third of that energy usage. A significant portion of the energy used by such large-scale computing centers is devoted to cooling since even small increases in operating temperatures can negatively impact the performance of microprocessors, memory devices, and other electronic components. While some of this energy is expended to operate the cooling systems that are directly cooling the chips (e.g., heat spreaders, heat pipes, etc.), energy consumption/costs for indirect cooling can also be quite staggering. Indirect cooling energy costs include, for example, cooling or air conditioning of data center buildings. Data center buildings can house thousands, to tens of thousands or more, of high-performance chips in server racks, and each of those high-performance chips is a heat source. An uncontrolled ambient temperature in a data center will adversely affect the performance of the individual chips and the data center system performance as a whole.

Thermal dissipation in high-power density chips (semiconductor devices/die) is also a critical challenge as improvements in chip performance, e.g., through increased gate or transistor density due to advanced processing nodes, evolution of multi-core microprocessors, etc., have resulted in increased power density and a corresponding increase in thermal flux that contributes to elevated chip temperatures. Higher density of transistors also increases the length of metal wiring on the chips, which generates its own additional thermal flux due to Joule heating of these wires due to higher currents. These elevated temperatures are undesirable as they can degrade the chip's operating performance, efficiency, reliability, and amount of remaining life. Cooling systems used to maintain the chip at a desired operating temperature typically remove heat using one or more heat dissipation devices, e.g., thermal spreaders, heat pipes, cold plates, liquid cooled heat pipe systems, thermal-electric coolers, heat sinks, etc. One or more thermal interface material(s), such as, for example, thermal paste, thermal adhesive, or thermal gap filler, may be used to facilitate heat transfer between the surfaces of a chip and heat dissipation device(s). A thermal interface material(s) (TIM(s)) is any material that is inserted between two components to enhance the thermal coupling therebetween. Unfortunately, the combined thermal resistance of (i) the thermal resistance of interfacial boundary regions between a TIM(s) and the chip and/or the heat dissipation device(s), and (ii) the thermal resistance of a thermal interface material(s) itself can inhibit heat transfer from the chip to the heat dissipation devices, undesirably reducing the cooling efficiency of the cooling system.

Generally speaking, there are multiple components between the heat dissipating sources (i.e., active circuitry) in the chips and the heat dissipation devices, each of which contributes to the system thermal resistance cumulatively along the heat transfer paths and raises chip junction temperatures from the ambient.

Such cooling systems can suffer from reduced cooling efficiency due to the design and manufacture of system components. In some other approaches, a device package includes a plurality of TIM layers and a heat spreader between a device and a single heat sink for which the heat spreader is in thermal contact with multiple devices in the package, thermally coupling the devices. This may undesirably increase operational cost and limit cooling and/or assembly flexibility of the device package.

Accordingly, there exists a need in the art for improved energy-efficient cooling systems, by reducing system thermal resistance, and methods of manufacturing the same.

### SUMMARY

Embodiments herein provide cooling apparatuses including an integrated cooling assembly and methods of manufacturing the cooling apparatuses, such as in a device package.

Advantageously, the cooling apparatuses described herein provide for a cooling manifold design having flexible assembly and structural integrity by including a combination of efficient heat dissipation devices, such as liquid cooling, for high power-density devices, such as ASICs in a device package, and other forms of heat dissipation, such as air cooling or other coolants using heat dissipation devices including heat spreaders, for lower power-density devices, such as memory stacks in the same device package. Beneficially, the cooling apparatus reduces demand for liquid cooling and reduces operational costs in a multi-chip module (MCM) by using other forms of heat dissipation for devices with lower thermal footprint, such as heat spreaders that use available airflows from forced and/or natural convection, and by providing liquid cooling for devices having higher thermal footprint. Beneficially, the cooling apparatus has a modular design that provides targeted cooling by using the combination of thermal solutions. Beneficially, the cooling manifold design avoids cross-heating between different devices within the same device package by decoupling the thermal solutions. That is, in an MCM, a liquid cooling module removes heat from an ASIC through a first heat transfer path, and air cooling removes heat from one or more memory devices through a second heat transfer path that is different from the first heat transfer path. Beneficially, the cooling apparatus has reduced thermal mass, faster cooling response time, and reduced system thermal resistance. Beneficially, the heat sinks of the cooling apparatus may have dimensions and weight that the lower power-density devices are capable of supporting as compared to other approaches where a single heat sink is disposed over the heat spreader and coupled to multiple devices within the device package. Beneficially, heat sink fins or other extended portions may extend over a cold plate in some embodiments, increasing heat sink surface area. Beneficially, the cooling apparatus is attached to the devices using a TIM layer with a reduced compression force and smaller device area. Beneficially, the cooling apparatus has fewer thermal interfaces (e.g., fewer TIM layers, no heat spreader) in a heat transfer path between a device and a coolant, desirably reducing cumulative thermal resistance.

One general aspect includes a cooling apparatus. The cooling apparatus includes an integrated cooling assembly. The integrated cooling assembly includes a first die and a cold plate having first and second portions, wherein the first portion is directly bonded to a backside of the first die. The second portion of the cold plate is spaced apart from the backside of the first die to define at least one fluid channel arranged for a liquid coolant between the second portion of the cold plate and the backside of the first die. The cooling apparatus further includes a plurality of second dies communicatively coupled to the first die and one or more heat sinks attached to at least one second die of the plurality of second dies, wherein the cold plate is thermally decoupled from the one or more heat sinks.

Implementations of the cooling apparatus may include one or more of the following features. The at least one fluid channel has at least one inlet and at least one outlet defined by the cold plate. The one or more heat sinks may be arranged for a gaseous coolant. The one or more heat sinks may comprise a first heat sink and a second heat sink that are attached to different respective dies of the plurality of second dies, wherein the integrated cooling assembly is disposed between the first heat sink and the second heat sink. The one or more heat sinks may comprise fins. The one or more heat sinks comprising fins may be disposed over the at least one second die, wherein the fins extend vertically away from the at least one second die, such as extending in a direction orthogonal to and away from a top surface of the second die. The one or more heat sinks comprising fins may be disposed laterally adjacent to the integrated cooling assembly, wherein the fins extend laterally away from the integrated cooling assembly and/or relative to the first die, such extending in a direction orthogonal to and away from a side surface of the first die of the integrated cooling assembly. The plurality of second dies may be disposed adjacent to a periphery of the integrated cooling assembly, wherein the one or more heat sinks may comprise a single heat sink attached to the plurality of second dies and disposed adjacent to the periphery of the integrated cooling assembly. The cooling apparatus may further comprise a manifold attached to the integrated cooling assembly, the manifold comprising one or more coolant channels in fluid communication with the at least one fluid channel. A heat sink of the one or more heat sinks may comprise a heat sink portion disposed over the integrated cooling assembly, wherein each coolant channel of the one or more coolant channels is disposed through a respective gap in the heat sink portion. Two or more second dies of the plurality of second dies may be disposed adjacent to different sides of the integrated cooling assembly, wherein the heat sink is attached to the two or more second dies. The cooling apparatus may further comprise a thermal insulator disposed within the respective gap between each coolant channel of the one or more coolant channels and the heat sink portion. A heat sink of the one or more heat sinks may be attached to the at least one second die through a thermal interface material layer disposed between the heat sink and the at least one second die. The first portion of the cold plate may be directly bonded to the backside of the first die through direct dielectric bonds formed between the cold plate and the first die. The first portion of the cold plate may be directly bonded to the backside of the first die through direct hybrid bonds formed between the cold plate and the first die. The cooling apparatus may further comprise an interposer, wherein the first die is communicatively coupled to each of the plurality of second dies through interconnections via the interposer. The cooling apparatus may further comprise a sealing material layer disposed between the integrated cooling assembly and the one or more heat sinks. The first die may comprise logic, and the plurality of second dies may comprise memory. A device package may include the cooling apparatus. The device package may further include a package substrate, wherein the integrated cooling assembly is attached to the package substrate. The device package may further include a package cover disposed over the integrated cooling assembly. The package cover may include an inlet opening and an outlet opening disposed therethrough, wherein the at least one fluid channel is in fluid communication with the inlet opening and the outlet opening of the package cover. The cold plate may include a perimeter sidewall comprising the first portion of the cold plate, a top portion comprising the second portion of the cold plate, and a cavity divider comprising cavity sidewalls. The perimeter sidewall may extend downwardly from the top portion to the backside of the first die to define a perimeter of the cold plate. The cavity divider may extend downwardly from the top portion towards the backside of the first die. The cavity sidewalls, the perimeter sidewall, and the backside of the first die may collectively define the at least one fluid channel therebetween.

One general aspect includes a method for manufacturing a cooling apparatus comprising an integrated cooling assembly, the integrated cooling assembly comprising a first die and a cold plate, wherein the cooling apparatus further comprises a plurality of second dies communicatively coupled to the first die and one or more heat sinks. The method includes directly bonding a first portion of the cold plate to a backside of the first die, wherein a second portion of the cold plate is spaced apart from the backside of the first die to define at least one fluid channel arranged for a liquid coolant between the second portion of the cold plate and the backside of the first die, and attaching the one or more heat sinks to at least one second die of the plurality of second dies, wherein the cold plate is thermally decoupled from the one or more heat sinks.

Implementations of the method for manufacturing the cooling apparatus may include one or more of the following features. The at least one fluid channel may have at least one inlet and at least one outlet defined by the cold plate. The one or more heat sinks may be arranged for a gaseous coolant. Directly bonding the first portion of the cold plate to the backside of the first die may comprise direct dielectric bonding or direct hybrid bonding. The one or more heat sinks may comprise a first heat sink and a second heat sink. Attaching the one or more heat sinks to the at least one second die may comprise attaching the first heat sink and the second heat sink to different respective dies of the plurality of second dies, wherein the integrated cooling assembly is disposed between the first heat sink and the second heat sink. Attaching the one or more heat sinks to the at least one second die may comprise disposing a thermal interface material layer on the at least one second die and attaching a heat sink of the one or more heat sinks to the at least one second die using the thermal interface material layer. Two or more second dies of the plurality of second dies may be disposed adjacent to different sides of the integrated cooling assembly. The method may further include attaching a manifold to the integrated cooling assembly, the manifold comprising one or more coolant channels in fluid communication with the at least one fluid channel, and attaching a heat sink of the one or more heat sinks to the two or more second dies, wherein the heat sink comprises a heat sink portion disposed over the integrated cooling assembly, the one or more coolant channels being disposed through respective gaps in the heat sink portion. The cold plate may include a perimeter sidewall comprising the first portion of the cold plate, a top portion comprising the second portion of the cold plate, and a cavity divider comprising cavity sidewalls. Directly bonding the first portion of the cold plate to the backside of the first die may include directly bonding the perimeter sidewall to the backside of the first die, wherein the perimeter sidewall extends downwardly from the top portion to the backside of the first die to define a perimeter of the cold plate, the cavity divider extends downwardly from the top portion towards the backside of the first die, and the cavity sidewalls, the perimeter sidewall, and the backside of the first die collectively define the at least one fluid channel therebetween.

### BRIEF DESCRIPTION OF THE DRAWINGS

The above and other objects and advantages of the disclosure will be apparent upon consideration of the following detailed description, taken in conjunction with the accompanying drawings, in which:

FIG. 1 illustrates a device package with an external heat sink;

FIG. 2A is a schematic plan view of an example of a system panel, in accordance with embodiments of the present disclosure;

FIG. 2B is a schematic partial sectional side view of a device package mounted on a PCB, in accordance with embodiments of the present disclosure;

FIG. 2C is a schematic exploded isometric view of the device package in FIG. 2B.

FIG. 3 is a schematic sectional view of an example device package, in accordance with embodiments of the present disclosure, that may be used with the system panel;

FIG. 4 is a schematic sectional view of an integrated cooling assembly of the device package, in accordance with embodiments of the present disclosure;

FIG. 5 shows a method that can be used to manufacture the device package described herein;

FIGS. 6A-B (collectively referred to as FIG. 6) show schematic sectional views of a cooling apparatus including an integrated cooling assembly and one or more heat sinks attached to a plurality of dies, in accordance with embodiments of the present disclosure;

FIGS. 7-8 show schematic plan views of semiconductor devices and example cooling apparatuses corresponding to the semiconductor devices, in accordance with embodiments of the present disclosure;

FIGS. 9A-B (collectively referred to as FIG. 9) show schematic sectional views of a cooling apparatus including an integrated cooling assembly and a single heat sink comprising a heat sink portion extending over the integrated cooling assembly, in accordance with embodiments of the present disclosure;

FIG. 10 shows a schematic sectional view of a device package including a cooling apparatus attached to a package substrate, the cooling apparatus having an integrated cooling assembly arranged for a liquid coolant and a plurality of heat sinks arranged for a gaseous coolant, in accordance with embodiments of the present disclosure; and

FIG. 11 shows a flow diagram for an example process that can be used to manufacture a cooling apparatus described herein, in accordance with embodiments of the present disclosure.

The figures herein depict various embodiments of the present disclosure for purposes of illustration only. It will be appreciated that additional or alternative structures, assemblies, systems, and methods may be implemented within the principles set out by the present disclosure.

### DETAILED DESCRIPTION

As used herein, the term “substrate” means and includes any workpiece, wafer, or article that provides a base material or supporting surface from which or upon which components, elements, devices, assemblies, modules, systems, or features of the heat-generating devices, packaging components, and cooling assembly components described herein may be formed or mounted. The term “substrate” also includes semiconductor substrates that provide a supporting material upon which elements of a semiconductor device are fabricated or attached, and any material layers, features, and/or electronic devices formed thereon, therein, or therethrough. Examples of substrate material that may be used in applications that generate high thermal density include, but are not limited to, Si, GaN, SiC, InP, GaP, InGaN, AlGaInP, AlGaAs, etc.

As described below, the semiconductor substrates herein generally have a “device side,” e.g., the side on which semiconductor device elements are fabricated, such as transistors, resistors, and capacitors, and a “backside” that is opposite the device side. The term “active side” should be understood to include a surface of the device side of the substrate and may include the device side surface of the semiconductor substrate and/or a surface of any material layer, device element, or feature formed thereon or extending outwardly therefrom, and/or any openings formed therein. Thus, it should be understood that the material(s) that forms the active side may change depending on the stage of device fabrication and assembly. Similarly, the term “non-active side” (opposite the active side) includes the non-active side of the substrate at any stage of device fabrication, including the surfaces of any material layer, any feature formed thereon, or extending outwardly therefrom, and/or any openings formed therein. Thus, the terms “active side” or “non-active side” may include the respective surfaces of the semiconductor substrate at the beginning of device fabrication and any surfaces formed during material removal, e.g., after substrate thinning operations. Depending on the stage of device fabrication or assembly, the terms “active sides” and “non-active sides” are also used to describe surfaces of material layers or features formed on, in, or through the semiconductor substrate, whether or not the material layers or features are ultimately present in the fabricated or assembled device. For example, in some instances, the term “active side” is used to indicate a surface of a substrate that will in the future, but does not yet, include semiconductor device elements.

Spatially relative terms are used herein to describe the relationships between elements, such as the relationships between substrates, heat-generating devices, cooling assembly components, device packaging components, and other features described below. Unless the relationship is otherwise defined, terms such as “above,” “over,” “upper,” “upwardly,” “outwardly,” “on,” “below,” “under,” “beneath,” “lower,” “top,” “bottom,” and the like are generally made with reference to the X, Y, and Z directions set forth by X, Y and Z axis in the drawings. Thus, it should be understood that the spatially relative terms used herein are intended to encompass different orientations of the substrate and, unless otherwise noted, are not limited by the direction of gravity. Unless the relationship is otherwise defined, terms describing the relationships between elements such as “disposed on,” “embedded in,” “coupled to,” “connected by,” “attached to,” “bonded to,” either alone or in combination with a spatially relevant term include both relationships with intervening elements and direct relationships where there are no intervening elements. Furthermore, the term “horizontal” or “lateral” is generally made with reference to the X-axis direction and the Y-axis direction set forth in the drawings. The term “vertical” is generally made with reference to the Z-axis direction set forth in the drawings.

Various embodiments disclosed herein include bonded structures in which two or more elements are directly bonded to one another without an intervening adhesive (referred to herein as “direct bonding,” “direct dielectric bonding,” or “directly bonded”). The resultant bonds formed by this technique may be described as “direct bonds” and/or “direct dielectric bonds.” In some embodiments, direct bonding includes the bonding of a single material on the first of the two or more elements and a single material on a second one of the two or more elements, where the single material on the different elements may or may not be the same. For example, bonding a layer of one inorganic dielectric (e.g., silicon oxide) to another layer of the same or different inorganic dielectric. As discussed in more detail below, the process of direct bonding (e.g., direct dielectric bonding) provides a reduction of thermal resistance between a semiconductor device and a cold plate. Examples of dielectric materials used in direct bonding include oxides, nitrides, oxynitrides, carbonitrides, and oxycarbonitrides, etc., such as, for example, silicon oxide, silicon nitride, silicon oxynitride, silicon carbonitride, silicon oxycarbonitride, etc. Direct bonding can also include bonding of multiple materials on one element to multiple materials on the other element (e.g., hybrid bonding). As used herein, the term “hybrid bonding” refers to a species of direct bonding having both i) at least one (first) nonconductive feature directly bonded to another (second) nonconductive feature, and ii) at least one (first) conductive feature directly bonded to another (second) conductive feature, without any intervening adhesive. The resultant bonds formed by this technique may be described as “hybrid bonds” and/or “direct hybrid bonds.” In some hybrid bonding embodiments, there are many first conductive features, each directly bonded to a second conductive feature, without any intervening adhesive. In some embodiments, nonconductive features on the first element are directly bond to nonconductive features of the second element at room temperature without any intervening adhesive, which is followed by bonding of conductive features of the first element directly bonded to conductive features of the second element via annealing at slightly higher temperatures (e.g. >100° C., >200° C., >250° C., >300° C., etc.)

Unless otherwise noted, the terms “cooling assembly” and “integrated cooling assembly” generally refer to a semiconductor device and a cold plate attached to the semiconductor device. Typically, the cold plate is formed with recessed surfaces that define one or more fluid cavities (e.g., fluid channels, coolant chamber volume(s), or coolant channel(s)) between the cold plate and the semiconductor device. In embodiments where the cold plate is formed with plural fluid cavities, each fluid cavity may be defined by cavity dividers and/or sidewalls of the cold plate. For example, cavity dividers may be spaced apart from each other and extend laterally between opposing cold plate sidewalls (e.g., in one direction between a first pair of opposing cold plate sidewalls, or in two directions between orthogonal pairs of opposing cold plate sidewalls). The cavity dividers and the cold plate sidewalls may collectively define adjacent fluid cavities therebetween. The cold plate may comprise a polymer material.

The cold plate may be attached to the semiconductor device by use of a compliant adhesive layer or by direct bonding or hybrid bonding. Direct bonding may include direct dielectric bonding techniques as described herein and may give rise to direct dielectric bonds. Hybrid bonding may include hybrid bonding techniques as described herein and may give rise to direct hybrid bonds. For example, the cold plate may include material layers and/or metal features that facilitate direct bonding or hybrid bonding with the semiconductor device. Beneficially, the backside of the semiconductor device is directly exposed to coolant fluids flowing through the integrated cooling assembly, thus providing for direct heat transfer therebetween. Unless otherwise noted, the integrated cooling assemblies described herein may be used with any desired fluid, e.g., liquid, gas, and/or vapor-phase coolants, such as water, glycol, etc.

Exemplary cooling fluids available for use in the various embodiments include: water (either purified or deionized), a glycol (e.g., ethylene glycol, propylene glycol), glycols mixed with water (e.g., ethylene glycol mixed with water (EGW) or propylene glycol mixed with water (PGW)), dielectric fluids (e.g. fluorocarbons, polyalphaolefin (PAO), isoparaffins, synthetic esters, or very high viscosity index (VHVI) oils), or mineral oils. Depending upon design and operating conditions, these fluids may be used in single-phase liquid, single-phase vapor, two-phase liquid/vapor or two-phase solid/liquid. Additionally, multiple combinations of the aforementioned cooling fluid phases may be employed in various hybrid configurations to meet the particular cooling needs of a respective implementation and still be within the scope of the contemplated embodiments.

Additionally, in some embodiments part or all the cooling is provided by gases. Exemplary gases include atmospheric air and/or one or more inert gases such as nitrogen. Atmospheric air may be taken to mean the mixture of different gases in Earth's atmosphere made up of about 78% nitrogen and 21% oxygen.

Depending on the design needs of a fluid cooling system using the disclosed embodiments, engineered dielectric cooling fluids may be used. Some examples of dielectric fluids used for cooling semiconductors include: 3M™ Fluorinert™ Liquid FC-40-A non-flammable, dielectric fluid that can be used in direct contact with live electronics; 3M™ Novec™ Engineered Fluids-A non-flammable, dielectric fluid that can be used in direct contact with live electronics; Galden® PFPE (perfluoropolyether) products used as heat transfer fluids; EnSolv Fluoro HTF-A solvent with a high boiling point and low pour point that can be used for semiconductor wafer cooling. It is understood that in the selection of the cooling fluid, system design aspects such as operating temperatures and pressures, fluid flow rates, fluid viscosity, and other properties will require evaluation when selecting the appropriate cooling fluid.

In some embodiments, the cooling fluids may contain microparticles and/or nanoparticle additives to enhance the conductivity of the cooling fluid within the integrated cooling assemblies. Choi and Eastman (1995) from Argonne National Laboratory, U.S.A. (Yu et al., 2007) coined the word “nanofluid.” The nanofluid is an engineered fluid prepared by suspending the nano-sized (1-100 nm) particles of metals/non-metals and their oxide(s) with a base/conventional fluid. The suspension of high thermal conductivity metals/non-metals and their oxides nanoparticles enhances the thermal conductivity and heat transfer ability, etc. of the base fluid. The additives to the underlying cooling fluid may comprise for example, nanoparticles of carbon nanotube, nanoparticles of graphene, or nanoparticles of metal oxides. When the cooling fluid contains microparticles, the microparticles are typically 10 microns or in in diameter. Silicon oxide microparticles may be used.

The concentration of these micro or nanoparticles may be less than 1%, less than 0.2%, or less than 0.05%. Depending upon the liquid and micro/nanoparticle type chosen for the nanofluid, higher concentrations of 10% or less, 5% or less, or 2% or less may be used. The cooling fluids may also contain small amounts of glycol or glycols (e.g., propylene glycol, ethylene glycol etc.) to reduce frictional shear stress and drag coefficient in the cooling fluid within the integrated cooling assembly. The availability of different base fluids (e.g., water, ethylene glycol, mineral or other stable oils, etc.) and different nanomaterials provide a variety of nanomaterial options for nanofluid solutions to be used in the various embodiments. These nanomaterial option groups such as aforementioned metals (e.g., Cu, Ag, Fe, Au . . . , etc.), metal oxides (e.g., TiO2, Al2O3, CuO . . . , etc.), carbons (e.g., carbon nanotubes (CNTs), graphene, diamond, graphite . . . , etc.), or a mixture of different types of nanomaterials. Metal nanoparticles (Cu, Ag, Au . . . ), metal oxide nanoparticles (Al2O3, TiO2, CuO), and carbon-based nanoparticles are commonly employed elements. Silicon oxide nanoparticles may also be used. Using nanofluids when practicing the various embodiments disclosed herein can result in increased heat removal efficiencies and effectiveness.

The fluid control design aspects of specific embodiments may require the nanofluids to be magnetic to facilitate either movement or cessation of movement of the fluids within the semiconductor structures. Magnetic nanofluids (MNFs) are suspensions of a non-magnetic base fluid and magnetic nanoparticles. The magnetic nanoparticles may be coated with surfactant layers such as oleic acid to reduce particle agglomeration and/or settling. Magnetic nanoparticles used in MNFs are usually made of metal materials (ferromagnetic materials) such as iron, nickel, cobalt, as well as their oxides such as spinel-type ferrites, magnetite (Fe3O4), and so forth. The magnetic nanoparticles used in MNFs typically range in size from about 1 to 100 nanometers (nm).

This disclosure describes embodiments involving the architecture of system and component elements that can be employed to provide for the cooling of semi-conductor components, packaging, and boards. However, those skilled in the art will appreciate the disclosed components and arrangements can be deployed and used in scenarios where component heat up or thermal warm up is desired for a component that is currently outside the low end of the desired operational range. Components that are outside the low end of their operational range can, if started in a cold environment, experience thermal warping or cracking up to and including thermal overexpansion and contact separation that may impair the successful operation of the system. Therefore, in these scenarios, the architectures and embodiments disclosed herein can be used where the indirect thermal solutions supporting them are repurposed or operated in a hybrid configuration to provide warming fluids or heat transfer media to accomplish the warm-up or heat-up scenario. These scenarios are controlled by systems not shown here to bring temperatures up at a speed or timing that enables the materials to avoid the excessive thermal expansion or unequal thermal expansion that may occur among the materials of the semiconductor or packaging being serviced by the thermal solution. Once the component or packaging is brought up into the normal operating range, it can be safely started and brought to a useful operational state.

Considering the warm-up or heat-up embodiments introduced above, the balance of this disclosure and terms used should be viewed in a light that also considers the design option for such warm-up or heat-up. Thus, where terms such as cooling channel, cooling chamber volume, and cooling port are used, for example, such terms could also be considered as a thermal control channel, a thermal control volume, or a thermal control port, respectively. A person of skill would understand that heat flux or heat transfer would go in a different direction, but the design concepts are similar and can be successfully employed in the various embodiments.

In some embodiments, a cooling channel is a liquid cooling channel, and a liquid may flow through the liquid cooling channel. In some embodiments, the liquid may comprise a water and/or glycol (e.g. propylene glycol, ethylene glycol, and mixtures thereof).

As described below, coolant fluid flowing through a cold plate may be used to control the temperature of semiconductor devices. The fluid flowing across the surface of the semiconductor device absorbs heat and conducts heat away from the semiconductor device.

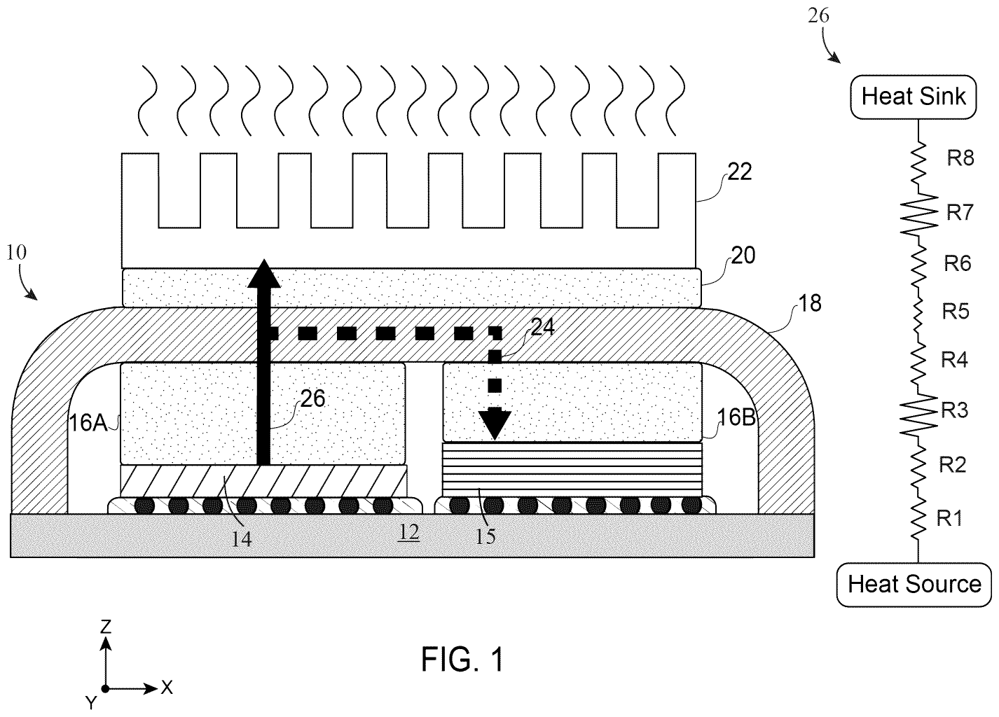

FIG. 1 is a schematic side view of a device package 10 and a heat sink 22 attached to the device package 10. The device package 10 typically includes a package substrate 12, a first device 14, a device stack 15, a heat spreader 18, and first TIM layers 16A, 16B thermally coupling the first device 14 and the device stack 15 to the heat spreader 18. The device package 10 is thermally coupled to the heat sink 22 through a second TIM layer 20. The TIM layers 16A, 16B, 20 facilitate thermal contact between components in the device package 10 and between the device package 10 and the heat sink 22.

As heat flux density increases with increasing power density in advanced semiconductor devices, the cumulative thermal resistance of the system illustrated in FIG. 1 is increasingly problematic as heat cannot be dissipated quickly enough to allow semiconductor devices to run at optimal power. Consequently, the energy efficiency of semiconductor devices is reduced. Furthermore, heat is transferred between semiconductor devices within the device package 10, as shown with heat transfer path 24 (illustrated as a dashed line), where heat may be undesirably transferred from the first device 14 having a high heat flux, such as a central processing unit (CPU) or a graphical processing unit (GPU), to the device stack 15 having low heat flux, such as memory, through the heat spreader 18.

For example, as shown in FIG. 1, each device package component, and the respective interfacial boundaries therebetween, have a corresponding thermal resistance that forms heat transfer path 26 (illustrated by arrow 26 in FIG. 1). The right-hand side of FIG. 1 illustrates the heat transfer path 26 as a series of thermal resistances R1-R8 between a heat source and a heat sink. Here, R1 is the thermal resistance of the bulk semiconductor material of the first device 14. R3 and R7 are the thermal resistances of the first TIM layers 16A, 16B and the second TIM layer 20, respectively. R5 is the thermal resistance of the heat spreader 18. R2, R4, R6, and R8 represent the thermal resistance at the interfacial region of the components (e.g., contact resistances). In a typical cooling system, R3 and R7 may account for 80% or more of the cumulative thermal resistance of the heat transfer path 26 and R5 may account for 5% or more. R1 of the first device 14 and R2, R4, R6, and R8 of the interfaces account for the remaining cumulative thermal resistance. Accordingly, embodiments described herein provide for integrated cooling assemblies embedded within a device package. The embedded cooling assemblies shorten the thermal resistance path between a semiconductor device and a heat sink and reduce thermal communication between semiconductor devices disposed in the same device package, such as described in relation to the figures below.

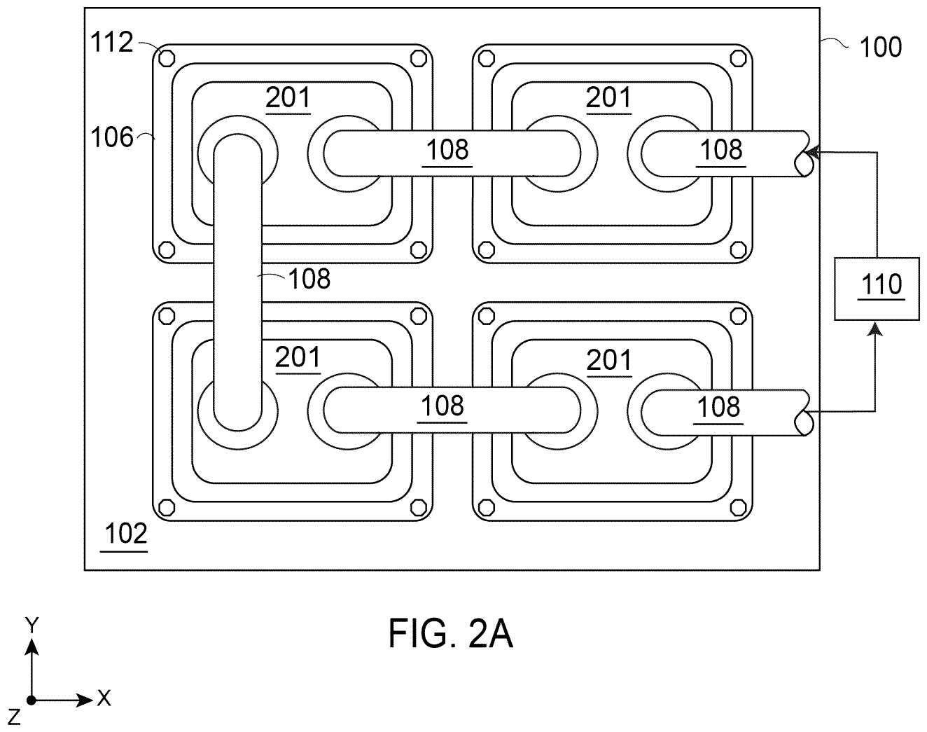

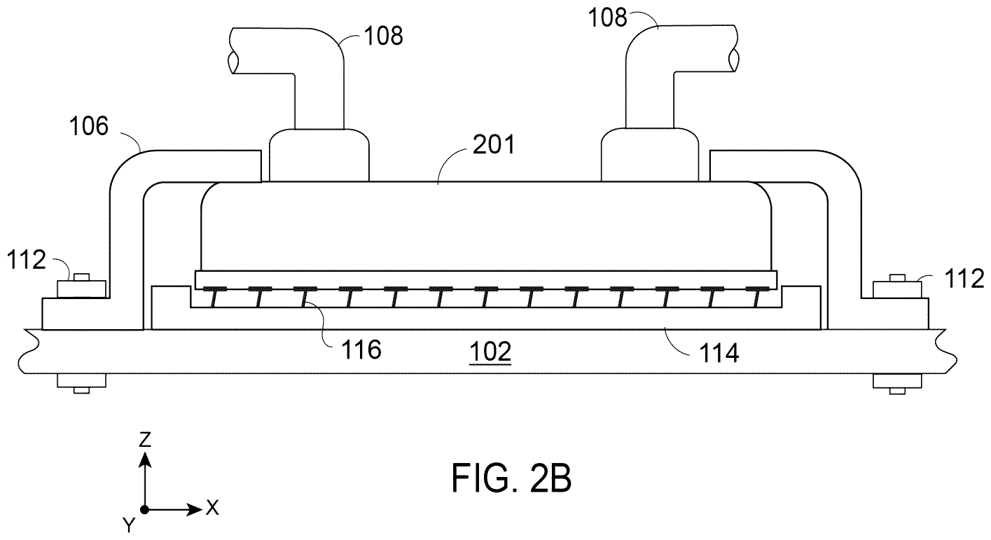

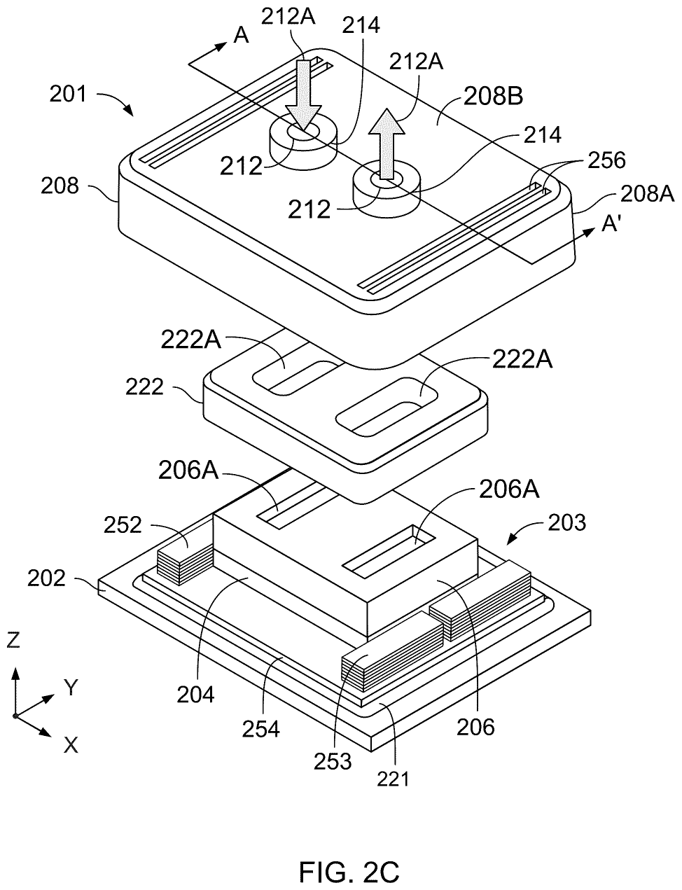

FIG. 2A is a schematic plan view of an example of a system panel 100, in accordance with embodiments of the present disclosure. Generally, the system panel 100 includes a printed circuit board (PCB) 102, a plurality of device packages 201 mounted to the PCB 102, and a plurality of coolant lines 108 fluidly coupling each of the device packages 201 to a coolant source 110. It is contemplated that coolant fluid may be delivered to each of the device packages 201 in any desired fluid phase, e.g., liquid, vapor, gas, or combinations thereof, and may flow out from each device package 201 in the same phase or a different phase. In some embodiments, the coolant fluid is delivered to the device packages 201 and returned therefrom as a liquid, whereby the coolant source 110 may comprise a heat exchanger or chiller to maintain the coolant fluid at a desired temperature. In other embodiments, the coolant fluid may be delivered to the device packages 201 as a liquid, vaporized to a vapor within the device packages 201, and returned to the coolant source 110 as a vapor. In those embodiments, the device packages 201 may be fluidly coupled to the coolant source 110 in parallel, and the coolant source 110 may include or further include a compressor (not shown) for condensing the received vapor to a liquid form.

FIG. 2B is a schematic partial sectional side view of a portion of the system panel 100 of FIG. 2A. As shown, each device package 201 is fluidly coupled to the plurality of coolant lines 108 and is disposed in a socket 114 of the PCB 102 and connected thereto using a plurality of pins 116, or by other suitable connection methods, such as solder bumps (not shown). The device package 201 may be seated in the socket 114 and secured to the PCB 102 using a mounting frame 106 and a plurality of fasteners 112, e.g., compression screws, collectively configured to exert a relatively uniform downward force on the upward facing edges of the device package 201. The uniform downward force ensures proper pin contact between the device package 201 and the socket 114.

FIG. 2C is a schematic exploded isometric view of an example device package 201, in accordance with embodiments of the present disclosure. Generally, the device package 201 includes a package substrate 202, an integrated cooling assembly 203 disposed on the package substrate 202, and a package cover 208 disposed on a peripheral portion of the package substrate 202. Suitable materials that may be used in the package cover 208 include copper, aluminum, metal alloys, etc. The package cover 208 extends over the integrated cooling assembly 203 so that the integrated cooling assembly 203 is disposed between the package substrate 202 and the package cover 208. The integrated cooling assembly 203 typically includes a semiconductor device 204 and a cold plate 206 bonded to the semiconductor device 204. In some embodiments, the cold plate 206 may comprise substrate material like silicon, glass, ceramic, etc. Although the lateral dimensions (or footprint) of the cold plate 206 are shown to be the same or similar to the lateral dimensions (or footprint) of the semiconductor device 204, the footprint of the cold plate 206 may be smaller or larger in one or both directions when compared to the footprint of the semiconductor device 204.

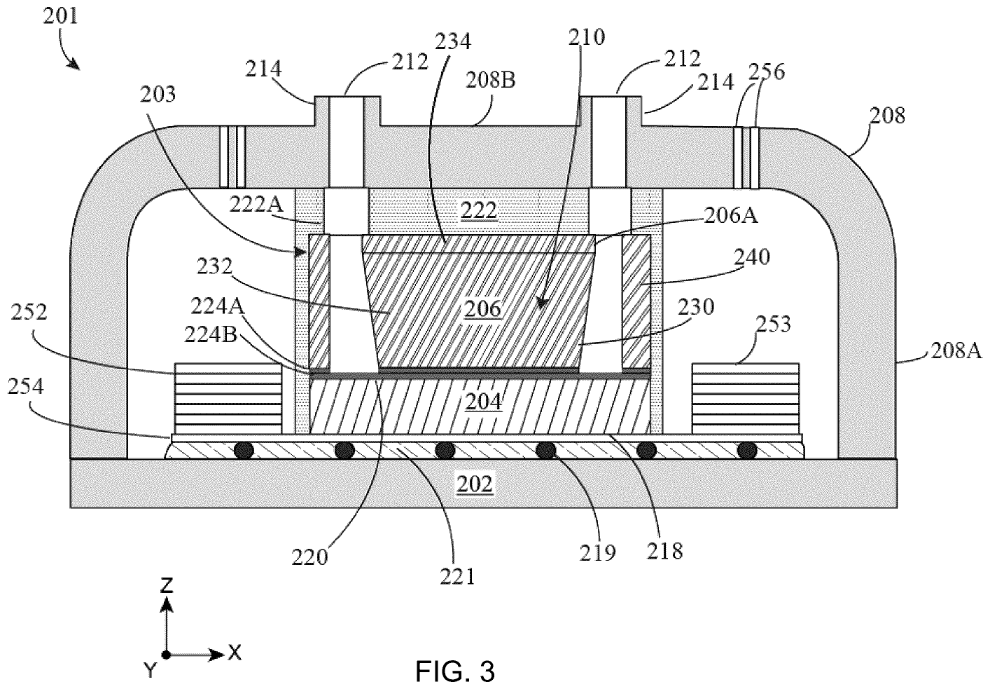

As shown, the device package 201 further includes a sealing material layer 222 that forms a coolant fluid impermeable barrier between the package cover 208 and the integrated cooling assembly 203 that prevents leaking of the coolant fluid outside of the cooling assembly and prevents coolant fluid from reaching an active side 218 (discussed below in relation to FIG. 3) of the semiconductor device 204 and causing damage thereto. In some embodiments, the sealing material layer 222 comprises an adhesive material that reliably attaches the package cover 208 to the integrated cooling assembly 203. In some embodiments, the sealing material layer 222 comprises a polymer or epoxy material that extends upwardly from the package substrate 202 to encapsulate and/or surround at least a portion of the semiconductor device 204. In some embodiments, the sealing material layer 222 may also comprise conductive material, e.g., solder. In other embodiments, the sealing material layer 222 is formed from a molding compound, e.g., a thermoset resin, that when polymerized, forms a hermetic seal between the package cover 208 and the cold plate 206. Here, the coolant fluid is delivered to the cold plate 206 through openings 222A disposed through the sealing material layer 222. As shown, the openings 222A are respectively in registration and fluid communication with inlet and outlet openings 212 of the package cover 208 thereabove and inlet and outlet openings 206A in the cold plate 206 therebelow.

It will be understood that the openings are shown in a section view. The openings may have any cross-sectional shape that allows fluid to flow therethrough (e.g., rectangular, square, hexagonal, or circular cross-sections). For example, the inlet and outlet openings 206A of the cold plate 206 may form an elongated shape extending from one side of the cold plate 206 to another side of the cold plate 206. For example, the inlet and outlet openings 206A may form any shape having a length greater than a width in the X-Y plane (e.g., a rectangular or a trapezoidal shape). A shape in the X-Y plane of the openings 222A disposed through the sealing material layer 222 may be substantially the same as the shape of the inlet and outlet openings 206A of the cold plate 206 in the same place. Furthermore, it will be understood that all references to an opening throughout the present disclosure refer to an opening defined by a sidewall (e.g., opening sidewall).

Generally, the package substrate 202 includes a rigid material, such as an epoxy or resin-based laminate, that supports the integrated cooling assembly 203 and the package cover 208. The package substrate 202 may include conductive features disposed in or on the rigid material that electrically couples the integrated cooling assembly 203 to a system panel, such as the PCB 102.

FIG. 3 is a schematic sectional view in the X-Z plane of the device package 201 taken along line A-A′ of FIG. 2C. As illustrated in FIG. 3, the semiconductor device 204 includes the active side 218 that includes device components, e.g., transistors, resistors, and capacitors, formed thereon or therein, and a non-active side, here the semiconductor device backside 220, opposite the active side 218. As shown, the active side 218 is positioned adjacent to and facing towards the package substrate 202. The active side 218 may be electrically connected to the package substrate 202 by use of conductive bumps 219, which are encapsulated by a first underfill layer 221 disposed between the semiconductor device 204 and the package substrate 202. The first underfill layer 221 may comprise a cured polymer resin or epoxy, which provides mechanical support to the conductive bumps 219 and protects against thermal fatigue. In some embodiments, the active side 218 may be electrically connected to another package substrate, another active die, or another passive die (e.g., interposer) using hybrid bonding or conductive bumps 219. The cold plate 206 may be disposed above the package substrate 202 with the semiconductor device 204 disposed therebetween. For example, the semiconductor device 204 (and the first underfill layer 221) may be disposed between the cold plate 206 and the package substrate 202. In some embodiments, the cold plate 206 may be disposed directly on the package substrate 202.

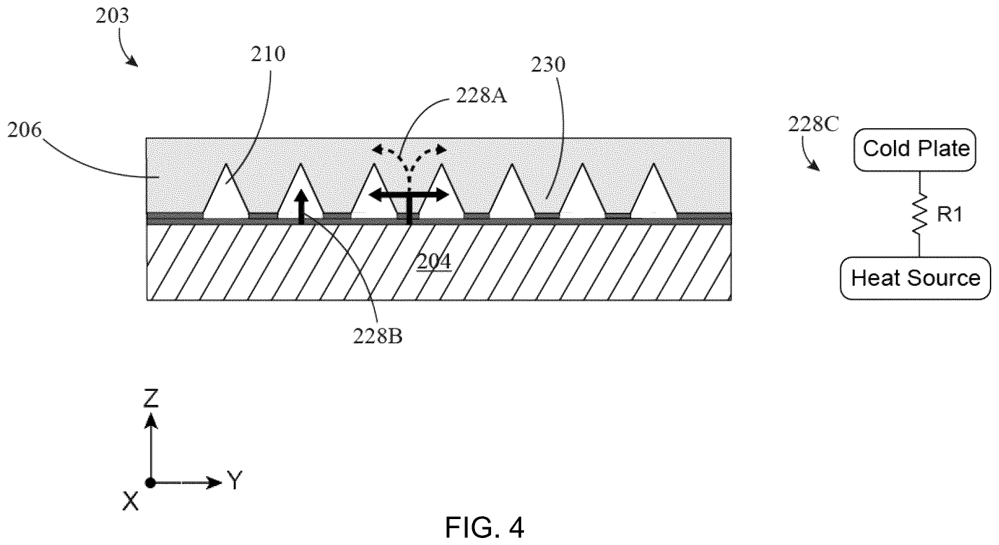

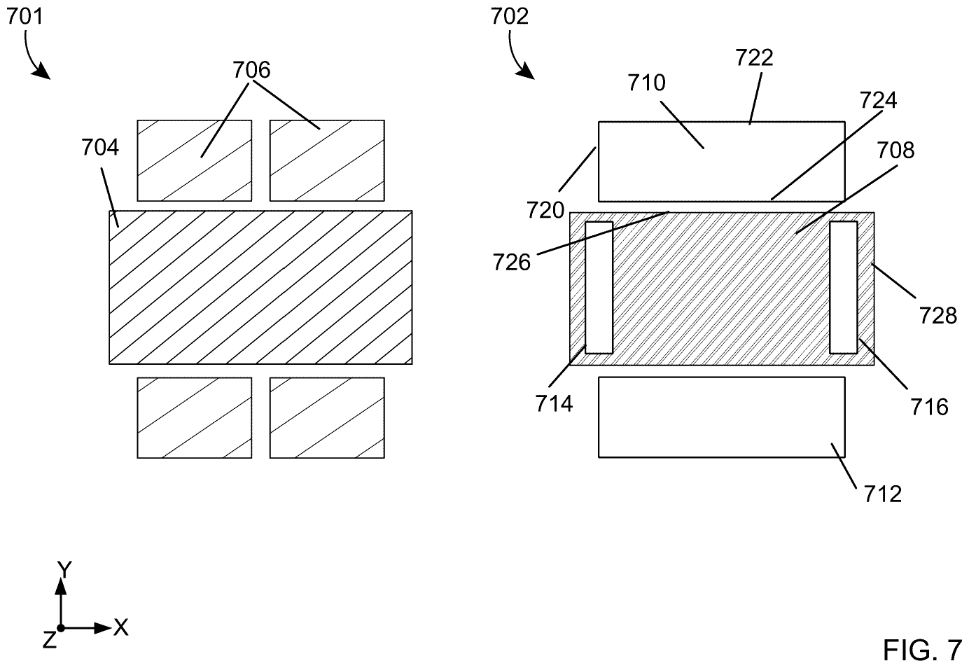

Here, the cold plate 206 comprises a top portion 234 and a sidewall 240 (e.g., a perimeter sidewall defining a perimeter of the cold plate 206) extending downwardly from the top portion 234 to the backside 220 of the semiconductor device 204. The top portion 234, the perimeter sidewall 240, and the backside 220 of the semiconductor device 204 collectively define a coolant channel 210 therebetween. The cold plate 206 comprises cavity dividers 230 extending downwardly from the top portion 234 towards the backside 220 of the semiconductor device 204. The cavity dividers 230 may extends laterally and in parallel between an inlet opening 206A of the cold plate 206 and an outlet opening 206A of the cold plate 206 to define coolant channels 210 therebetween. It should be appreciated that, the cold plate 206 may comprise one cavity divider 230 which forms two coolant channels (e.g., one coolant channel on either side of the cavity divider 230) by means of the cavity divider 230 and portions of the perimeter sidewall 240. More specifically, coolant channels 210 may be formed between the cavity divider 230 and a portion of the perimeter sidewall 240 extending parallel to the cavity divider 230. Alternatively, in other embodiments, the cold plate 206 may comprise plural cavity dividers 230, for example two cavity dividers (as illustrated in FIG. 7), five cavity dividers, or six cavity dividers (as illustrated in FIG. 4). In such examples, the cold plate 206 comprises more than two coolant channels 210, for example three coolant channels, four coolant channels, seven coolant channels, or more, defined between the cavity dividers 230 and/or the cavity divider(s) 230 and the perimeter sidewall 240.

The cavity dividers 230 comprise cavity sidewalls 232 which form surfaces of corresponding coolant channels 210. In embodiments where plural cavity dividers 230 extend in parallel to each other, cavity sidewalls 232 of adjacent cavity dividers 230 are opposite (e.g., facing) each other. In embodiments comprising a single cavity divider 230, a first cavity sidewall may be opposite (e.g., face) a first portion of the perimeter sidewall 240 extending parallel to and facing the first cavity sidewall. A second cavity sidewall may be opposite (e.g., face) a second portion of the perimeter sidewall 240 extending parallel to and facing the second cavity sidewall. The first portion of the perimeter sidewall 240 may be an opposite side of the cold plate 206 to the second portion of the perimeter sidewall 240. For example, in embodiments where the cold plate 206 is rectangular, first and second opposing sides of the rectangular cold plate 206 form the first and second portions of the perimeter sidewall 240.

The cavity dividers 230 may be continuous cavity dividers which extend continuously (e.g., in the Y-axis direction) between the inlet opening 206A and the outlet opening 206A of the cold plate 206.

With reference to FIG. 3, coolant channels 210 may be defined by:
the backside 220 of the semiconductor device 204, which forms lower coolant channel surfaces;
portions of the perimeter sidewall 240 extending in the Y-axis direction, which form end surfaces of the coolant channels 210;
the cavity sidewalls 232, which form inner surfaces of the coolant channels 210 in the X-axis direction; and
portions of the perimeter sidewall 240 extending in the X-axis direction, which form outer surfaces of the coolant channels 210 in the X-axis direction.

Here, the cavity sidewalls 232 are formed at an acute angle with respect to the backside 220 of the semiconductor device 204 such that upper portions of opposing (e.g., facing) cavity sidewalls 232 meet. Therefore, the cavity sidewalls 232 and the backside 220 of the semiconductor device 204 collectively define a triangular cross-section of the coolant channel 210.

In some embodiments, the backside 220 of the semiconductor device 204 comprises a corrosion protective layer (not shown). The corrosion protective layer may be a continuous layer disposed across the entire backside 220 of the semiconductor device 204, such that the cold plate 206 is attached thereto. Beneficially, the corrosion protective layer provides a corrosion-resistant barrier layer, thus preventing undesired corrosion of the semiconductor device 204 (e.g., the semiconductor substrate material which might otherwise be in direct contact with coolant fluid flowing through a coolant chamber volume 210).

One or more coolant chamber volumes may include one or more coolant channels. The coolant channels may extend between a single inlet opening and a single outlet opening of the cold plate 206, such that the coolant chamber volume(s) and/or coolant channel(s) share the same inlet and outlet openings. In some embodiments, multiple inlet and/or outlet openings may be coupled to the coolant chamber volume(s).

In embodiments having plural coolant chamber volumes and/or plural coolant channels, each coolant chamber volume and/or coolant channel may be connected between a separate inlet opening and a separate outlet opening. In such embodiments, the coolant fluid may be directed to the separate inlet openings and from the separate outlet openings using a manifold disposed above the openings in the Z-axis direction.

In some embodiments, a height in the Z-axis direction of the coolant chamber volume(s) and or coolant channel(s) may be greater than 100 μm, 100 μm-1000 μm, or 100 μm-700 μm. A width in the Y-axis direction of the coolant chamber volume(s) and/or coolant channel(s) may be greater than 100 μm, 100 μm-1000 μm, or 100 μm-700 μm. For example, the width of the coolant chamber volume(s) and/or coolant channel(s) may be greater than the height. A cross-section of the coolant chamber volume(s) and/or coolant channel(s) in the Y-Z plane is wide enough to allow for a pressure drop of 0-20 psi, 3-15 psi, or 4-10 psi.

In some embodiments, preparing a desired surface roughness of the sidewalls of the coolant chamber volume(s) and/or coolant channels may include depositing an organic layer on a photoresist layer after cold plate features have been etched to form a micro-masking layer, such as between 1 to 30 nm. The micro-masking layer may be dry etched to form the desired surface roughness, such as between 0.1 to 3.0 nm.

With reference to FIG. 3, the cold plate 206 is attached to the backside 220 of the device 204 without the use of an intervening adhesive. For example, the cold plate 206 may be directly bonded to the backside 220 of the device 204, such that the cold plate 206 and the backside 220 of the device 204 are in direct contact. For example, in some embodiments, one or both of the cold plate 206 and the backside 220 of the semiconductor device 204 may comprise a dielectric material layer, e.g., a first dielectric material layer 224A and a second dielectric material layer 224B respectively, and the cold plate 206 is directly bonded to the backside 220 of the semiconductor device 204 through bonds formed between the dielectric material layers 224A, 224B. In some embodiments, one of the cold plate 206 or the backside 220 of the semiconductor device 204 may comprise a thin bonding dielectric layer (e.g., silicon nitride, etc.) and other element(s) may not include any such explicit bonding dielectric layer (or can have only a native oxide layer). Here, the first and second dielectric material layers 224A, 224B are illustrated as continuous layers, but it will be understood that one or both of the layers may not be continuous.

It is contemplated that one or both of the dielectric material layers 224A, 224B, or any portion thereof, may be optional. For example, the first dielectric material layer 224A may be disposed only on lower surfaces of the cold plate 206 facing the backside 220 of the semiconductor device 204. With reference to FIG. 4, described below, portions of the first dielectric material layer 224A may be disposed only on lower surfaces of support features (e.g., the cavity dividers 230). In some embodiments, no bonding layer is disposed within the coolant channels 210. That is, portions of the dielectric material layers 224A, 224B may not be disposed within a channel volume (e.g., fluid channel(s)), and there is no bonding layer (e.g., dielectric material) over substrate portions of the device 204 disposed within the channel volume (e.g., fluid channel(s)). Additionally, or alternatively, the backside 220 of the device 204 may comprise a corrosion protective material (not shown) disposed over the substrate portions of the device 204 within the channel volume (e.g., fluid channel(s)). Beneficially, directly bonding the cold plate 206 to the semiconductor device 204, as described above, reduces the thermal resistance therebetween and increases the efficiency of heat transfer from the semiconductor device 204 to the cold plate 206. In particular, thermal resistance is reduced by directly bonding lower surfaces of the cavity dividers 230 facing the semiconductor device 204 to the backside 220 of the semiconductor device 204.

Here, the cold plate 206 is a single contiguous structure having a partial sectional side view in the X-Z plane as shown at FIG. 3. In some embodiments, the cold plate 206 may be collectively formed by a plurality of segments or sections. That is, the cold plate 206 may comprise the top portion 234 (e.g., an upper Z-direction section) attached to a lower portion (e.g., a lower Z-direction section) that comprises the cavity dividers 230. The top portion 234 may be attached to the lower portion through direct bonding, such as direct dielectric bonding, or through respective bonding or adhesive layers, such as one or more intervening dielectric material layers disposed between the top portion 234 and the lower portion. In some embodiments, the top portion 234 of the cold plate 206 is a base substrate (e.g., comprising a perimeter sidewall and/or a patterned side) and one or more support features, such as the cavity dividers 230, are attached to the top portion 234. Additionally, the cavity dividers 230 may comprise a plurality of segments or sections, such as a stack of layers (not shown) that form a support feature (e.g., a cavity divider 230). The plurality of segments or sections forming such a cavity divider may be attached through direct bonding, such as direct dielectric bonding, or through respective bonding or adhesive layers, such as one or more intervening dielectric material layers disposed between a first layer and an adjacent second layer of a stack of layers that form a support feature (e.g., a cavity divider 230). It is appreciated that the cold plate 206, or portions thereof, may comprise any number of segments or sections that are assembled and attached (e.g., using direct dielectric bonds) such that leakage of a coolant fluid is desirably prevented.

In some embodiments, the device package 201 includes one or more devices, such as memory devices 252, 253, disposed adjacent to the integrated cooling assembly 203. Here, the device 204 and the memory devices 252, 253 are disposed in a side-by-side arrangement on another die, such as an interposer 254, over the package substrate 202 and are in electrical communication with one another through conductive features (e.g., interconnects, pads, vias such as through substrate vias (TSVs), wiring, routing layers, etc.) formed in, on, or through the interposer 254. The memory devices 252, 253 may include stacked memory dies such as high bandwidth memory (HBM). The memory devices 252, 253 are communicatively coupled to the device 204. The memory devices 252, 253 are bonded to the interposer 254, wherein the bonding forms interconnections through the interposer 254 between the device 204 and each of the memory devices 252, 253.

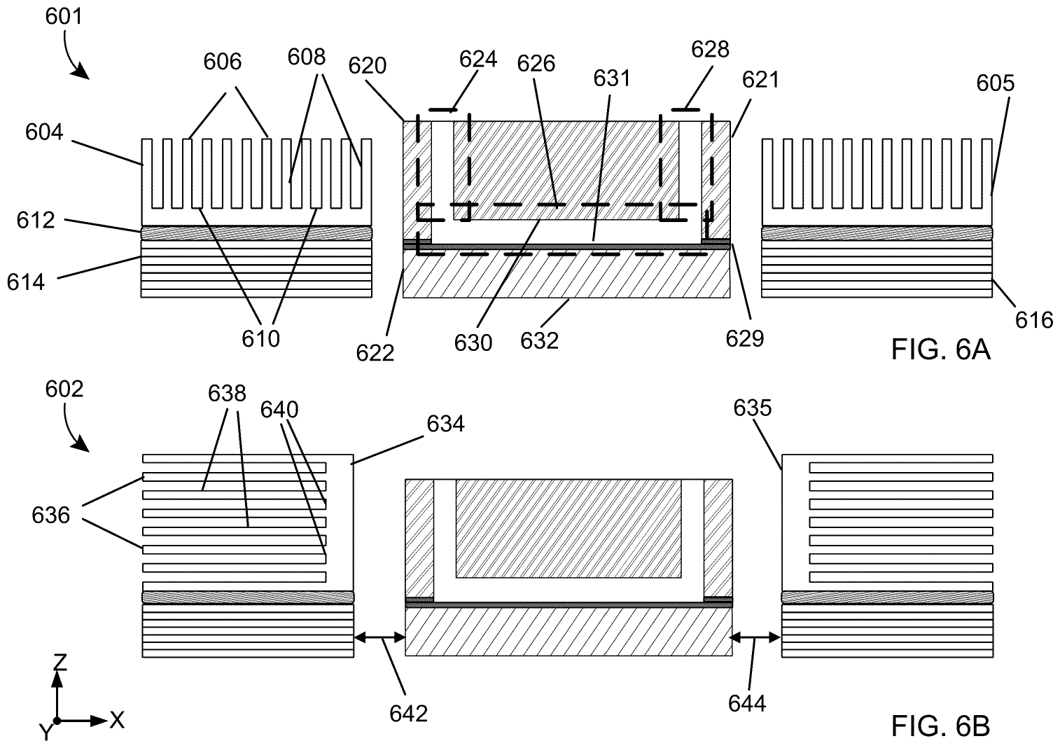

Generally, the device 204 has a higher processor density (e.g., higher transistor density) than the memory devices 252, 253 and is expected to generate higher operating temperatures than the memory devices 252, 253. In some embodiments, the package cover 208 includes airflow openings, such as airflow openings 256 disposed at a lateral portion 208B that connects sidewall portions 208A of the package cover 208. The sealing material layer 222 extends upwardly to the lateral portion 208B and prevents leaking of coolant fluid outside of the openings 222A. Here, the sealing material layer 222 does not encapsulate the memory devices 252, 253. In some embodiments, the sealing material layer 222 leaves at least a portion of the memory devices 252, 253 unencapsulated. Doing so permits air cooling of the memory devices 252, 253 through forced or natural convection from the airflow openings 256. In some embodiments, a thermal interface material is deposited between the memory devices 252, 253 and the package cover 208 such that memory devices 252, 253 and the package cover 208 are in thermal contact. In some embodiments, the package cover 208 is a heat spreader. The package cover 208 may comprise a metal, such as copper. In some embodiments, a thickness of a topmost die of the memory die stack (e.g., memory devices 252, 253) along the Z-axis orthogonal to the device backside 220 is greater than a thickness of the deposited thermal interface material along the Z-axis such that the deposited TIM layer is thin between the topmost die of the memory die stack and the package cover 208. In some embodiments, one or more heat dissipation devices may be attached to the memory devices 252, 253 as described with respect to FIGS. 6-11. The attached heat dissipation device(s) can be arranged for a different coolant than the integrated cooling assembly 203. That is, the memory devices 252, 253 can be cooled using a gaseous coolant whereas the device 204 can be cooled with a liquid coolant. Here, the airflow openings 256 are disposed above the memory devices 252, 253. It is noted that any number of airflow openings may be disposed at any part of the package cover 208, such as the sidewall portions 208A. Optionally, the memory devices 252, 253 do not have a heat sink attached thereto, and sides of the memory devices 252, 253 are exposed to the gaseous coolant.

In some embodiments, the package substrate 202 may include or be an interposer. That is, one or more devices, such as the device 204 and/or any of the memory devices 252, 253, may be micro-bump bonded on an interposer using conductive bumps, such as the conductive bumps 219, and molded to form an assembly, where the cold plate 206 is attached (e.g., directly bonded) to the respective backsides of the two or more devices (e.g., the backsides of the device 204 and another device). The assembly may be flip chip bonded to a substrate, such as an organic substrate. It is contemplated that mounting the device and/or other components to a package substrate, an interposer, etc., may include depositing a reflowable conductive material, such as conductive balls or bumps, coined solder balls, and other variants, for forming interconnections therebetween.

It is contemplated that interconnections between a first device (e.g., the device 204 or any other device or component described herein), one or more second devices (e.g., the devices 252, 253), and/or an interposer (e.g., the interposer 254) may be formed using various interconnect techniques and combinations thereof, such as micro-bump bonding, flip chip bonding, etc. In some embodiments, one or more devices may include conductive bumps disposed between a device and an interposer, such as solder bumps, such as microbumps. That is, any of the first device 204 and/or the plurality of second devices may be attached to a first side of the interposer 254, here an upper Z-direction side of the interposer 254, using micro-bump bonding and/or flip chip bonding. The interconnections between the first device 204 and/or the plurality of second devices are formed through connections between a respective device and the interposer 254 using the conductive bumps, such as microbumps between the first device 204 and the first side of the interposer 254 and/or microbumps between any of the second devices 252, 253 and the first side of the interposer 254.

Attaching one or more devices to an interposer may include micro-bump bonding, flip chip bonding, and/or variants thereof, and/or combinations thereof. Attaching the first device 204 and the plurality of second devices to the interposer may form an assembly. The assembly may be flip chip bonded to a substrate, such as the package substrate 202. That is, a conductive reflowable material, such as solder, may be deposited on interconnects disposed at a second side of the interposer 254, here a lower Z-direction side of the interposer 254, which is opposite to the first side of the interposer 254. The assembly may be flipped and positioned over the substrate. The assembly is positioned such that the second side of the interposer faces towards and is attached to the substrate. The conductive reflowable material may be reflowed, such as using hot air reflow, to form connections between the interposer 254 and the substrate and to form connections between the first device 204, any of the plurality of second devices, and the substrate through the interposer 254.

FIG. 4 is a schematic sectional view in the Y-Z plane of the integrated cooling assembly 203. In FIG. 4, the cold plate 206 comprises a patterned side that faces towards the semiconductor device 204 and an opposite side that faces towards the package cover 208 (not shown). The patterned side comprises a coolant chamber volume having plural coolant channels 210, which extend laterally between the inlet and outlet openings 106A of the cold plate 206. Each coolant channel 210 comprises cavity sidewalls which define a corresponding coolant channel 210. Portions of the cold plate 206 between the cavity sidewalls form support features (e.g., the cavity dividers 230). The support features (e.g., the cavity dividers 230) provide structural support to the integrated cooling assembly 203 and disrupt laminar fluid flow at the interface of the coolant and the device backside 220, resulting in increased heat transfer therebetween. Furthermore, by introducing plural coolant channels 210 to define separate coolant flow paths, an internal surface area of the cold plate 206 is increased, which further increases the efficiency of heat transfer.

In FIG. 4, arrows 228A and 228B illustrate two different heat transfer paths (respectively labeled paths 228A, 228B) in the integrated cooling assembly 203. A first heat transfer path illustrated by arrow 228B shows heat generated by the semiconductor device 204 transferring directly from the semiconductor material of the semiconductor device 204 to coolant fluid flowing through the cold plate 206. A second heat transfer path illustrated by arrows 228A shows heat generated by the semiconductor device 204 being transferred from semiconductor material (e.g., silicon material) of the semiconductor device 204 to semiconductor material (e.g., silicon material) of the cold plate 206 structure, propagated throughout the semiconductor material of the cold plate 206 structure (shown as dashed lines), and being transferring into coolant fluid flowing through the cold plate 206. A thermal resistance of the first and second heat transfer paths 228A, 228B is illustrated by heat transfer path 228C, which is shown as thermal resistance R1 between a heat source and a cold plate. Here, R1 is the thermal resistance of the bulk semiconductor material of the semiconductor device 204. It can be seen that the heat transfer path 228C of the integrated cooling assembly 203 is reduced compared to the heat transfer path 26 of the device package 10 of FIG. 1, due to the direct bonding discussed above.

In some embodiments, the cold plate 206 may be attached to the semiconductor device 204 using a hybrid bonding technique, where bonds are formed between the dielectric material layers 224A, 224B (see FIG. 3) and between metal features, such as between first metal pads and second metal pads, disposed in the dielectric material layers 224A, 224B.

Suitable dielectrics that may be used as the dielectric material layers 224A, 224B include silicon oxides, silicon nitrides, silicon oxynitrides, silicon carbon nitrides, metal-oxides, metal-nitrides, silicon carbide, silicon oxycarbides, silicon oxycarbonitride, diamond-like carbon (DLC), or combinations thereof. In some embodiments, one or both of the dielectric material layers 224A, 224B are formed of an inorganic dielectric material, e.g., a dielectric material substantially free of organic polymers. Typically, one or both of the dielectric layers are deposited to a thickness greater than the thickness of a native oxide, such as about 1 nanometer (nm) or more, 5 nm or more, 10 nm or more, 50 nm or more, or 100 nm or more. In some embodiments, one or both of the layers are deposited to a thickness of 3 micrometers or less, 1 micrometers or less, 500 nm or less, such as 100 nm or less, or 50 nm or less. The dielectric layer material and thickness may be optimized for lower thermal resistance between the die and the cold plate. For example, a first dielectric material layer comprising native oxide, the first dielectric material layer having a thickness in the Z-direction of about 1 nm to about 5 nm, may be disposed on a semiconductor substrate (e.g., silicon). The first dielectric material layer comprising the native oxide may be directly bonded to a second dielectric material layer comprising a same or different dielectric material, the second dielectric material layer having a thickness in the Z-direction of about 1 nm to about 5 nm. That is, a bonding layer comprising native oxide may be bonded to another bonding layer comprising a native oxide or another dielectric material.

It is noted that any of the cold plate 206 or the backside 220 of the first device 204 may comprise one or more bonding layers (e.g., comprising a dielectric material such as silicon nitride, etc.), and other element(s) may not include any such explicit bonding dielectric layer (or can have only a native oxide layer). Here, the dielectric layer 224A is illustrated as having non-continuous portions. That is, the dielectric layer 224A may include dielectric material portions disposed on lower Z-direction surfaces of the cold plate 206, such as a perimeter sidewall of the cold plate 206 and/or the cavity dividers 230. It will be understood that the one or more dielectric layers may be continuous. That is, the dielectric material portions disposed on lower surfaces of the cold plate 206 may be part of a bonding layer disposed on at least a portion of the cold plate 206. The dielectric layer 224A may include a portion that extends along a perimeter of the cold plate 206 in the X-Y plane, such as between the perimeter sidewalls of the cold plate 206 and the backside 220 of the first device 204.

The cold plate 206 may be formed of any suitable material that has sufficient structural strength to withstand the desired pressures of coolant flowing into the coolant chamber volume 210. For example, the cold plate 206 may be formed of semiconductor material like silicon or other engineered materials like glass. In other examples, the cold plate 206 may be formed of a material selected from a group comprising polymers, metals, ceramics, or composites thereof. In some embodiments, the cold plate 206 may be formed of stainless steel (e.g., from a stainless-steel metal sheet) or a sapphire plate.

In some embodiments, the cold plate 206 may be formed of a bulk material having a substantially similar coefficient of linear thermal expansion (CTE) to the bulk material of the substrate 202 and/or the semiconductor device 204, where the CTE is a fractional change in length of the material (in the X-Y plane) per degree of temperature change. In some embodiments, the CTEs of the cold plate 206, the substrate 202, and/or the semiconductor device 204 are matched so that the CTE of the substrate 202 and/or the semiconductor device 204 is within about +/−20% or less of the CTE of the cold plate 206, such as within +/−15% or less, within +/−10% or less, or within about +/−5% or less when measured across a desired temperature range. In some embodiments, the CTEs are matched across a temperature range from about −60° C. to about 100° C. or from about −60° C. to about 175° C. In one example embodiment, the matched CTE materials each include silicon.

In some embodiments, the cold plate 206 may be formed of a material having a substantially different CTE from the semiconductor device 204, e.g., a CTE mismatched material. In such embodiments, the cold plate 206 may be attached to the semiconductor device 204 by a compliant adhesive layer (not shown) or a molding material that absorbs the difference in expansion between the cold plate 206 and the semiconductor device 204 across repeated thermal cycles.

The package cover 208 shown in FIGS. 2C and 3 generally comprises one or more vertical or sloped sidewall portions 208A and a lateral portion 208B that spans and connects the sidewall portions 208A. The sidewall portions 208A may extend upwardly from a peripheral surface of the package substrate 202 to surround the device 204 and the cold plate 206 disposed thereon. The lateral portion 208B may be disposed over the cold plate 206 and is typically spaced apart from the cold plate 206 by a gap corresponding to the thickness of the sealing material layer 222. Coolant is circulated through the coolant chamber volume 210 through the inlet and outlet openings 212 of the package cover 208 formed through the lateral portion 208B. The inlet and outlet openings 206A of the cold plate 206 may be in fluid communication with the inlet and outlet openings 212 of the package cover 208 through the inlet and outlet openings 222A formed in the sealing material layer 222 disposed therebetween. In certain embodiments, coolant lines 108 (FIGS. 2A-2B) may be attached to the device package 201 by use of connector features formed in the package cover 208, such as threads formed in the sidewalls of the inlet and outlet openings 212 of the package cover 208 and/or protruding features 214 that surround the inlet and outlet openings 212 and extend upwardly from a surface of the lateral portion 208B.

Typically, the package cover 208 is formed of semi-rigid or rigid material so that at least a portion of the downward force exerted on the package cover 208 by the mounting frame is transferred to a supporting surface of the package substrate 202 and not transferred to the cold plate 206 and the semiconductor device 204 therebelow. In some embodiments, the package cover 208 is formed of a thermally conductive metal, such as aluminum or copper. In such embodiments, the package cover 208 functions as a heat spreader that redistributes heat from one or more electronic components of the semiconductor device 204.

It should be noted that the direction in which the coolant fluid flows through the cold plate 206 may be controlled depending on the relative locations of the inlet and outlet openings. For example, the coolant fluid may flow from left to right in the device package 201 of FIG. 3 when the inlet openings 212, 222A, 206A of the package cover 208, the sealing material layer 222, and the cold plate 206, respectively, are located on the left-hand side of the device package 201 and the outlet openings 212, 222A, 206A of the package cover 208, the sealing material layer 222, and the cold plate 206, respectively, are located on the right-hand side of the device package 201. Alternatively, the coolant fluid may flow from right to left in the device package 201 illustrated in FIG. 3 when the outlet openings 212, 222A, 206A of the package cover 208, the sealing material layer 222, and the cold plate 206 are located on the left-hand side of the device package 201 and the inlet openings 212, 222A, 206A of the package cover 208, the sealing material layer 222, and the cold plate 206 are located on the right-hand side of the device package 201. Although only one set of inlet and outlet openings are shown and described here, additional inlet and outlet openings may also be provided at various locations on the package cover 208, the sealing material layer 222, and the cold plate 206.

An example flow path of the coolant fluid through the coolant chamber volume 210 may be as follows:

1. Coolant fluid enters the coolant chamber volume 210 through the inlet openings.
2. Coolant fluid flows across the inside surfaces of the cold plate 206 and absorbs heat generated by the semiconductor device 204 which has dissipated into the cold plate 206 structure. The coolant fluid may also flow directly across the backside 220 of the semiconductor device 204 to absorb heat energy directly from the semiconductor device 204. The coolant chamber volume 210 may additionally have various channels formed to direct the coolant fluid flow from inlet opening(s) to outlet opening(s) and facilitate heat extraction from the semiconductor device 204 by the coolant fluid. In some embodiments, the coolant fluid may be in direct contact with the backside 220 of the semiconductor device 204 or via one or more substrate or layers between the coolant fluid or backside 220 of the semiconductor device 204.
3 Coolant fluid exits the coolant chamber volume 210 through outlet openings.

It will be understood from the above flow path that heat is extracted without introducing an unnecessary thermal resistance (e.g., a TIM disposed between the backside 220 of the semiconductor device 204 and the cold plate 206) between the backside 220 of the semiconductor device 204 and the cold plate 206.

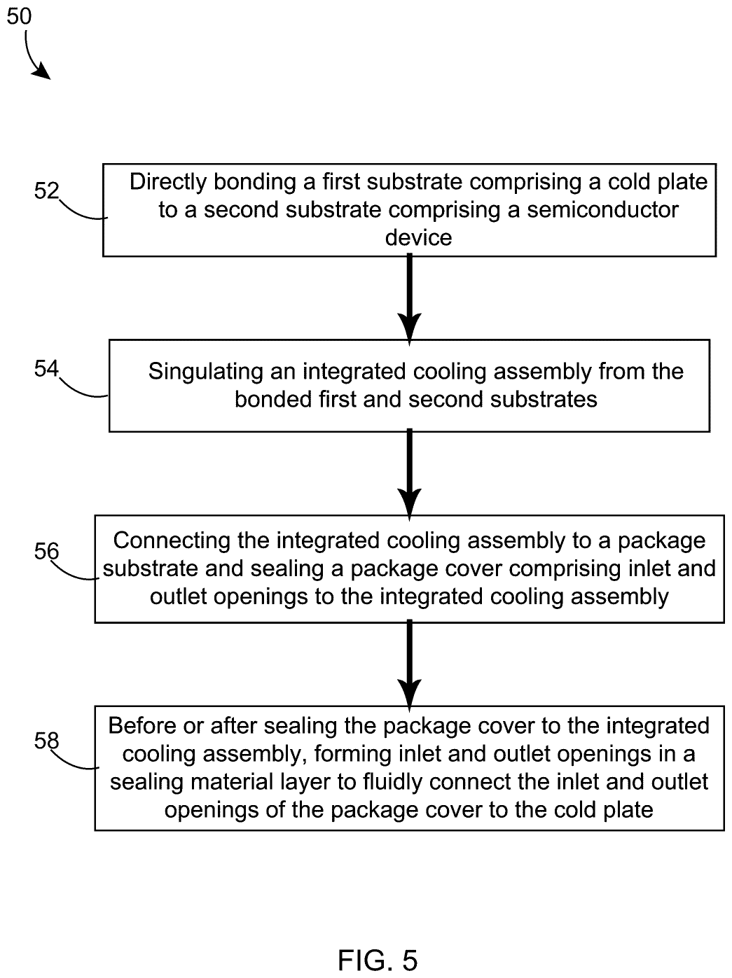

FIG. 5 is a flow diagram showing a method 50 of forming an integrated cooling assembly, according to embodiments of the present disclosure. Generally, the method 50 includes bonding a first substrate comprising one or more cold plates 206 to a second substrate comprising one or more semiconductor devices 204, and singulating one or more integrated cooling assemblies 203 from the bonded first and second substrates. For example, a wafer (e.g., a bare or reconstituted wafer) comprising one or more cold plates 206 can be directly bonded to another wafer (e.g., another bare or reconstituted wafer) comprising one or more semiconductor devices 204.

It will be understood that the first substrate may be a cold plate die or part of a wafer of cold plates. Further, the second substrate may be a semiconductor device die or part of a wafer of semiconductor devices 204. Therefore, the method 50 may include die-to-die direct bonding (e.g., cold plate die to semiconductor device die), water-to-die direct bonding (e.g., cold plate die to semiconductor device wafer, or cold plate wafer to semiconductor device die), and wafer-to-wafer direct bonding (e.g., cold plate wafer to semiconductor device wafer). It will be understood that the singulation step (discussed in relation to block 54, below) may not be required for a die-to-die direct bonding operation.

For simplicity, the following description is focused on forming one integrated cooling assembly 203 comprising one cold plate 206 and one semiconductor device 204. However, as mentioned above, in some embodiments, the first substrate may comprise plural cold plates 206 and the second substrate may comprise plural semiconductor devices 204, such that plural integrated cooling assemblies 203 may be formed from the first and second substrates.

At block 52, the method 50 includes directly bonding the first substrate (e.g., a monocrystalline silicon wafer) comprising a cold plate 206 to the second substrate (e.g., a monocrystalline silicon wafer) comprising a semiconductor device 204 without an intervening adhesive.

In some embodiments, the first substrate may be etched using a patterned mask layer formed on its surface to form features of the cold plate 206. An anisotropic etch process may be used, which uses inherently differing etch rates for the silicon material as between {100} plane surfaces and {111} plane surfaces when exposed to an anisotropic etchant.

In some embodiments, the etching process is controlled to where the etch rates of the substrate surfaces have a ratio between about 1:10 and about 1:200, such as between about 1:10 and about 1:100, for example between about 1:10 and 1:50, or between about 1:25 and 1:75. Examples of suitable anisotropic wet etchants include aqueous solutions of potassium hydroxide (KOH), ethylene diamine and pyrocatechol (EPD), ammonium hydroxide (HN₄OH), hydrazine (N₂H₄), or tetra methyl ammonium hydroxide (TMAH). The actual etch rates of the silicon substrate depend on the concentration of the etchant in the aqueous solution, the temperature of the aqueous solution, and a concentration of the dopant in the substrate (if any). Typically, the mask layer is formed of a material that is selective to anisotropic etch compared to the underlying monocrystalline silicon substrate. Examples of suitable mask materials include silicon oxide (SiₓO_{y}) or silicon nitride (SiₓN_{y}). In some embodiments, the mask layer has a thickness of about 100 nm or less, such as about 50 nm or less, or about 30 nm or less. The mask layer may be patterned using any suitable combination of lithography and material etching patterning methods.

The second substrate may include a bulk material, and a plurality of material layers disposed on the bulk material. The bulk material may include any semiconductor material suitable for manufacturing semiconductor devices, such as silicon, silicon carbide, silicon germanium, germanium, group III-V semiconductor materials, group II-VI semiconductor materials, or combinations thereof. While some high-performance processors like CPUs, GPUs, neural processing units (NPUs), and tensor processing units (TPUs) are typically made out of silicon, some other high power density (hence substantial heat-generating) devices may comprise silicon carbide or gallium nitride, for example. In some embodiments, the second substrate may include a monocrystalline wafer, such as a silicon wafer, a plurality of device components formed in or on the silicon wafer, and a plurality of interconnect layers formed over the plurality of device components. In other embodiments, the second substrate may comprise a reconstituted substrate, e.g., a substrate formed from a plurality of singulated devices embedded in a support material. In some embodiments, each semiconductor device may have its own individual cold plate fabricated through a reconstitution process.

The bulk material of the second substrate may be thinned after the semiconductor device 204 is formed using one or more backgrinding, etching, and polishing operations that remove material from the backside. Thinning the second substrate may include using a combination of grinding and etching processes to reduce the thickness (in the Z-direction) to about 450 μm or less, such as about 200 μm or less, or about 150 μm or less or about 50 μm or less. After thinning, the backside 220 may be polished to a desired smoothness using a chemical mechanical polishing (CMP) process, and the dielectric material layer may be deposited thereon. In some embodiments, the dielectric material layer may be polished to a desired smoothness to prepare the second substrate for the bonding process. In some embodiments, the method 50 includes forming a plurality of metal features in the dielectric material layer in preparation for a hybrid bonding process, such as by use of a damascene process.

In some embodiments, the active side of the second substrate is temporarily bonded to a carrier substrate (not shown) before or after the thinning process. When used, the carrier substrate provides support for the thinning operation and/or for the thinned material to facilitate substrate handling during one or more of the subsequent manufacturing operations described herein.

Here, the method 50 may include forming dielectric layers on one or both the first and second substrates, and directly bonding includes forming dielectric bonds between a first dielectric material layer of the first substrate and a second dielectric material layer of the second substrate (or forming dielectric bonds between one substrate and a dielectric material layer of the other substrate). Direct bonding processes join dielectric layers by forming strong chemical bonds (e.g., covalent bonds) between the dielectric layers.

Generally, directly bonding the surfaces (of the dielectric material layers formed on the first and second substrates) includes preparing, aligning, and contacting the surfaces. Examples of dielectric material layers include silicon oxide, silicon nitride, silicon oxynitride, and silicon carbonitride. Preparing the surfaces may include smoothing the respective surfaces to a desired surface roughness, such as between 0.1 to 3.0 nm RMS, activating the surfaces to weaken or open chemical bonds in the dielectric material, and terminating the surfaces with a desired species. Smoothing the surfaces may include polishing the first and second substrates using a CMP process. Activating and terminating the surfaces with a desired species may include exposing the surfaces to radical species formed in a plasma. The bond interface between the bonded dielectric layers can include a higher concentration of materials from the activation and/or last chemical treatment processes compared to the bulk of the bonding layers. For example, in some embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces.

In some embodiments, the plasma is formed using a nitrogen-containing gas, e.g., N₂, and the terminating species includes nitrogen, or nitrogen and hydrogen. In some embodiments, fluorine may also be present within the plasma. In some embodiments, the surfaces may be activated using a wet cleaning process, e.g., by exposing the surfaces to an aqueous ammonia solution. In some embodiments, the dielectric bonds may be formed using a dielectric material layer deposited on only one of the first and second substrates, but not on both. In those embodiments, the direct dielectric bonds may be formed by contacting the deposited dielectric material layer of one of the first and second substrates directly with a bulk material surface (or such a surface with a native oxide) of the other substrate.

Directly forming direct dielectric bonds between the first and second substrates at block 52 may include bringing the prepared and aligned surfaces into direct contact at a temperature less than 150° C., such as less than 100° C., for example, less than 30° C., or about room temperature, e.g., between 20° C. and 30° C. Without intending to be bound by theory, in the case of directly bonding surfaces terminated with nitrogen and hydrogen (e.g., NH₂ groups), it is believed that the hydrogen terminating species diffuse from the interfacial bonding surfaces, and chemical bonds are formed between the remaining nitrogen species during the direct bonding process. In some embodiments, the direct bond is strengthened using an anneal process, where the substrates are heated to and maintained at a temperature of greater than about 30° C. and less than about 450° C., for example, greater than about 50° C. and less than about 250° C., or about 150° C., for a duration of about 5 minutes or more, such as about 15 minutes. Typically, the bonds will strengthen over time even without the application of heat. Thus, in some embodiments, the method does not include heating the substrates.

In embodiments where the first and second substrates are bonded using hybrid dielectric and metal bonds, the method 50 may further include planarizing or recessing the metal features below the dielectric field surface before contacting and bonding the dielectric material layers. After the dielectric bonds are formed, the first and second substrates may be heated to a temperature of 150° C. or more and maintained at the elevated temperature for a duration of about 1 hour or more, such as between 8 and 24 hours, to form direct metallurgical bonds between the metal features.

Suitable direct dielectric and hybrid bonding technologies that may be used to perform aspects of the methods described herein include ZiBond® and DBI®, each of which are commercially available from Adeia Holding Corp., San Jose, CA, USA.

At block 54, the method 50 includes singulating at least one integrated cooling assembly 203 from the bonded first and second substrates. Singulation after bonding may impart distinctive structural characteristics on the integrated cooling assembly 203 as the bonding surface of the cold plate 206 has the same perimeter as the backside of the semiconductor device 204 bonded thereto. Thus, the sidewalls (e.g., side surfaces) of the cold plate 206 are typically flush with the edges (e.g., side surfaces) of the semiconductor device 204 about their common perimeters. In some embodiments, the cold plate 206 is singulated from the first substrate using a process that cuts or divides the first substrate in a vertical plane, i.e., in the Z-direction. In those embodiments, the side surfaces of the cold plate 206 are substantially perpendicular to the backside 220 of the semiconductor device 204, i.e., a horizontal (X-Y) plane of an attachment interface between the semiconductor device 204 and the cold plate 206. In some embodiments, the cold plate 206 is singulated using a saw or laser dicing process.

At block 56, the method 50 may include connecting the integrated cooling assembly 203 to the package substrate 202 and sealing a package cover 208 comprising inlet and outlet openings 212 to the integrated cooling assembly 203 by use of a molding compound that when cured, forms a sealing material layer 222.

At block 58, the method 50 may include, before or after sealing the package cover 208 to the integrated cooling assembly 203, forming inlet and outlet openings 222A in the sealing material layer 222 to fluidly connect the inlet and outlet openings 212 of the package cover 208 to the cold plate 206.

FIG. 6 shows schematic sectional views of example cooling apparatuses 601, 602 in the X-Z plane, each cooling apparatus including an integrated cooling assembly and one or more heat sinks. The integrated cooling assembly, or at least a portion thereof such as a cold plate, may be thermally decoupled from the one or more heat sinks. That is, the integrated cooling assembly corresponds to a first heat transfer path and the one or more heat sinks correspond to a second heat transfer path that is different from the first heat transfer path such that heat is not transferred between the integrated cooling assembly and each of the one or more heat sinks. FIG. 6A shows the cooling apparatus 601 including an integrated cooling assembly 620 comprising a cold plate 621 having at least a portion attached to a backside of a first die 622, here a die backside 631, and one or more heat sinks respectively attached to one or more second dies. Here, a left heat sink 604 is attached to a left second die 614, and a right heat sink 605 is attached to a right second die 616. Any of the second dies 614, 616 may be a single die or a die stack comprising two or more dies. The second dies 614, 616 are disposed adjacent to a periphery of the integrated cooling assembly 620. The integrated cooling assembly 620 is thermally decoupled from the one or more heat sinks 604, 605. Here, the cold plate 621 and/or the first die 622 are spaced apart from the one or more heat sinks 604, 605 and are arranged for different heat transfer paths. Here, the one or more heat sinks 604, 605 include vertical fins 606 that extend vertically along the positive Z-direction orthogonal to and away from a heat sink base 610. The heat sink base 610 extends laterally in the X-Y plane. Here, the heat sinks 604, 605 are arranged for a gaseous coolant. The thickness of the heat sinks 604, 605 in the Z-direction orthogonal to the heat sink base 610 may be different than the thickness of the integrated cooling assembly 620 in the same direction. Here, the thickness of the heat sinks 604, 605 in the Z-direction orthogonal to the heat sink base 610 is less than the thickness of the integrated cooling assembly 620 in the same direction.

FIG. 6B shows the cooling apparatus 602 including an integrated cooling assembly, such as the integrated cooling assembly 620, and one or more heat sinks 634, 635 attached to second dies, such as the second dies 614, 616. The cold plate and/or the first die are thermally decoupled from the one or more heat sinks 634, 635. Here, the one or more heat sinks 634, 635 include lateral fins 636 that extend laterally along the X-direction orthogonal to and away from a heat sink base 640 and are arranged for a gaseous coolant. The heat sink base 640 extends vertically along the Z-direction away from a second die attached thereto. The thickness of the heat sinks 634, 635 in the Z-direction orthogonal to the die backside 631 may be the same or different than the thickness of the integrated cooling assembly 620 in the same direction. Here, the overall thickness of the heat sinks 634, 635 and attached second dies in the Z-direction is greater than the thickness of the integrated cooling assembly 620 in the Z-direction. The thickness of the heat sinks 634, 635 may also be greater than the thickness of the integrated cooling assembly 620 in the Z-direction.

In some embodiments, the one or more heat sinks attached to the second dies do not include fins. That is, the one or more heat sinks may include a heat spreader that is substantially planar, such as a flat heat spreader, attached to one or more second dies. In some embodiments, the one or more heat sinks include a first heat sink attached to the one or more second dies and a second heat sink attached to the first heat sink. That is, a flat heat spreader may be attached to the one or more second dies using a first TIM layer disposed therebetween. A second heat sink, such as a heat sink including fins or other extended portions, may be attached on the flat heat spreader using a second TIM layer disposed therebetween.

The one or more heat sinks 604, 605, 634, 635 are attached to their respective heat sinks by one or more TIM layers, such as a TIM layer 612 disposed between the heat sink 604 and the second die 614. A device package may comprise a cooling apparatus as described herein, such as the cooling apparatuses 601, 602. The device package may comprise a package substrate, wherein the cooling apparatus is attached to the package substrate. Advantageously, as described with respect to FIG. 4, the cooling apparatuses 601, 602 do not include a heat spreader. That is, a device package including the cooling apparatus 601 does not include a heat spreader disposed between the heat sinks 604, 605 and the corresponding second dies, such as the second dies 614, 616, or a heat spreader disposed between the cold plate 621 and the first die 622. Further, the cooling apparatus 601 includes fewer thermal interfaces (e.g., fewer TIM layers) in a heat transfer path starting from a die, such as the first die 622 or one of the second dies 614, 616, to a coolant fluid. Here, the cooling apparatus 601 includes a single TIM layer 612 disposed between the second die 614 and the heat sink 604. This desirably reduces the cumulative thermal resistance in their respective heat transfer paths as described with respect to FIG. 4.

Here, the cold plate 621 includes a first portion, such as the perimeter sidewall 240 as described with reference to FIG. 3, that is attached to the first die 622. A second portion of the cold plate 621, such as a top portion comprising a cold plate frontside 630, is spaced apart from a first side of the first die 622, such as a die backside 631. The space between the second portion comprising the cold plate frontside 630 and the die backside 631 defines at least one fluid channel, such as the coolant chamber volume 210 as described with reference to FIG. 3. The at least one fluid channel may be arranged for any coolant fluid, such as a liquid coolant, a vapor coolant, a gaseous coolant, two-phase coolants, etc. Here, the at least one fluid channel is arranged for a liquid coolant. That is, the at least one fluid channel includes an inlet portion 624, a lateral channel portion 626, and an outlet portion 628. The lateral channel portion 626 is part of a fluid pathway between the inlet portion 624 and the outlet portion 628. The at least one fluid channel provides an interface between the die backside 631 and a coolant fluid, such as a liquid coolant. The cold plate 621 is attached to the first die 622 such that the coolant fluid is desirably prevented from leaking, such as through direct bonding as described in the following paragraphs. Heat may be removed from the first die 622 by the cold plate 621 via one or more heat transfer paths, such as the paths 228A, 228B as described with respect to FIG. 4.

In some embodiments, a first portion of the cold plate 621 (e.g., a perimeter sidewall) may be directly bonded to the die backside 631 of the first die 622. That is, the cold plate 621 may be attached to the first die 622 through direct bonds between the first portion of the cold plate 621 and the die backside 631. Here, the cold plate 621 may be attached to the first die 622 through direct dielectric bonds or direct hybrid bonds between the perimeter sidewall of the cold plate 621 and the die backside 631 of the first die 622. Here, the first portion of the cold plate 621 is directly bonded to the die backside of the first die 622 through bonds formed between the one or more dielectric material layers 629 between the lower Z-direction surfaces of the perimeter sidewall (and/or cavity dividers) and upper Z-direction surfaces of the die backside 631, as described with respect to FIG. 3. The one or more dielectric material layers 629 may correspond to the dielectric material layers 224A and/or 224B. It is noted and appreciated that the dielectric material layer 629 may not be continuous. For example, the dielectric material layer 629 may be disposed only on lower surfaces of the cold plate 621 facing a side of the first die 622. With reference to FIG. 4, portions of the dielectric material layer 629 may be disposed only on lower surfaces of the cold plate 621, such as lower Z-direction surfaces of the support features 230. Here, the dielectric material layer 629 extends over a portion of the die backside 631 disposed within the fluid channel(s). In some embodiments, the dielectric material layer 629 may extend up to the inner perimeter sidewalls of the cold plate 621 that define the fluid channel(s) and the perimeter of the cold plate 621 in the X-Y plane. That is, portions of the dielectric material layer 629 may define a gap above the die backside 631 disposed within the fluid channel(s).

The first side, such as the cold plate frontside 630, of the cold plate 621 may be patterned for increasing heat transfer between an interface of a coolant and the die backside 631. Here, the first die 622 includes a second side, here shown as an active side 632. The first die 622 may be communicatively coupled to each of the second dies 614, 616. That is, the active side 632 may include one or more device components. The device components may be electrically connected to components of the second dies 614, 616, such as through interconnections in a substrate, an active die, a passive die, etc. In some embodiments, the first die 622 and the second dies 614, 616 are bonded to an interposer (as described with respect to FIGS. 3, 9, and 10), wherein the bonding forms interconnections between the first die 622 and each of the second dies 614, 616 through at least a portion of the interposer. That is, the first die 622 and/or any of the second dies 614, 616 may be electrically connected to the interposer using solder, conductive bumps such as microbumps, interconnect pads, conductive vias, etc., where the interposer includes a communicative pathway between the connectors of the first die 622 and any of the second dies 614, 616. Any of the first die 622 and/or the second dies 614, 616 may be attached to the interposer through one or more interconnect techniques, such as micro-bump bonding, flip chip bonding, etc., as described with respect to FIG. 3.

The cooling apparatus 601 further includes the heat sinks 604, 605 respectively attached to the second dies 614, 616. Here, the second dies 614, 616 are device stacks, such as memory devices. The heat sinks 604, 605 may be attached using a TIM layer disposed on the second dies 614, 616, such as the TIM layer 612. The heat sinks 604, 605 comprise portions extending vertically in the Z-direction, away from their respective second dies 614, 616. That is, the heat sink 604 comprises the heat sink base 610 attached to the second die 614 and comprises the vertical fins 606 that extend vertically in the positive Z-direction starting from the heat sink base 610 and along vertical fin sidewalls 608. Here, the heat sinks 604, 605 are arranged for a gaseous coolant, where the vertical fins 606 provide a heat transfer interface between the gaseous coolant (e.g., air) and the heat sinks 604, 605 for heat dissipation using forced or natural convection.

The cooling apparatus 602 includes the heat sinks 634, 635 attached to at least one second die. Here, the heat sinks 634, 635 comprise portions extending laterally in the X-direction. That is, the heat sinks 634, 635 include the heat sink base 640, and the lateral fins 636 extend laterally starting from the heat sink base 640 and along lateral fin sidewalls 638, such as towards or away from the integrated cooling assembly 620. Here, the heat sinks 634, 635 are attached to the second die(s) at a different side of the heat sinks 634, 635 than the heat sink base 634, such as a sidewall of the heat sinks 634, 635. Here, the heat sinks 634, 635 are arranged for a gaseous coolant, where the lateral fins 636 provide a heat transfer interface between the gaseous coolant (e.g., air) and the heat sinks 634, 635 for heat dissipation using forced or natural convection. In some embodiments, one or both of the heat sinks 634, 635 include the heat sink base 640 but do not have lateral fins, such as a flat heat spreader.

In some embodiments, the one or more heat sinks 604, 605, 634, 635 comprise a metal, such as copper, aluminum, brass, nickel, etc. In some embodiments, a portion of the heat sinks, such as the vertical fins 606, may comprise a different material than another portion of the heat sinks, such as the heat sink base 610. That is, the vertical fins 606 may comprise a material and/or coating having a higher thermal conductivity than the heat sink base 610.

The cold plate 621 is thermally decoupled from the one or more heat sinks, such as the heat sinks 604, 605, 634, and 635. In some embodiments, the first die 622 includes logic or other compute elements (e.g. CPU, GPU, NPU, TPU, DPU, etc.). That is, the first die 622 may include high power-density (e.g., substantial heat-generating) components. In some embodiments, the second dies 614, 616 includes memory, peripherals, or other passive elements. That is, the second dies 614, 616 may include components that consume less power and/or may have a lower operating temperature than the first die 622. In some embodiments, the first die 622 comprises logic (e.g. CPU, GPU, NPU, TPU, DPU, etc.), and one or more of the second dies, such as the second dies 614, 616, comprise high-bandwidth memory (HBM). Here, the first die 622 may have a higher heat flux than the left second die 614 and/or the right second die 616. Beneficially, heat transfer between the first die 622 and the second dies 614, 616 is desirably mitigated or prevented by thermally decoupling the cold plate 621 from the one or more heat sinks, such as any of the heat sinks 604, 605, 634, and 635. Here, the integrated cooling assembly 620 is spaced apart from the heat sink(s) by gaps 642, 644. In some embodiments, the integrated cooling assembly 620 may be disposed adjacent to the second die 614 and the heat sinks 604 and spaced apart at about the same distance as the second die 616 and the heat sink 605. In some embodiments, the integrated cooling assembly 620 may be disposed at different distances from one or more of the second dies 614, 616. In some embodiments, a layer (not shown) may be deposited within the gaps 642, 644 between the integrated cooling assembly 620, or portions thereof, and the heat sinks 604, 605, 634, and 635, such as a sealing material layer as described with respect to FIGS. 3, 9, and 10. That is, a sealing material layer may be disposed between the integrated cooling assembly 620 and the heat sinks 604, 605. As described with respect to FIG. 3, the layer may comprise an organic material, a polymer, an epoxy, a molding compound, etc. In some embodiments, the layer comprises at least one of a polymer, an epoxy, molding compound, such as a resin.

It is contemplated that the heat sinks 604, 605, 634, 635 may include any number of fins or other extended portions having any suitable dimensions and geometries for cooling as described herein. That is, the vertical fins 606 may have rectangular cross-sectional geometries for a gaseous coolant but is not intended to be limited to such geometries. It is noted and appreciated that other types of heat sinks may be included within the principles set forth by the present disclosure. Some example types of heat sinks include plate-type fins, pin-type fins, flared-type fins, inverted fins, variants thereof, and/or combinations thereof. It is contemplated that the TIM layer 612 is intended to be illustrative and that the heat sinks 604, 605, 634, 635 may be attached to one or more second dies, such as the second dies 614, 616, by various means. Some examples include a thermally conductive adhesive and/or epoxy.

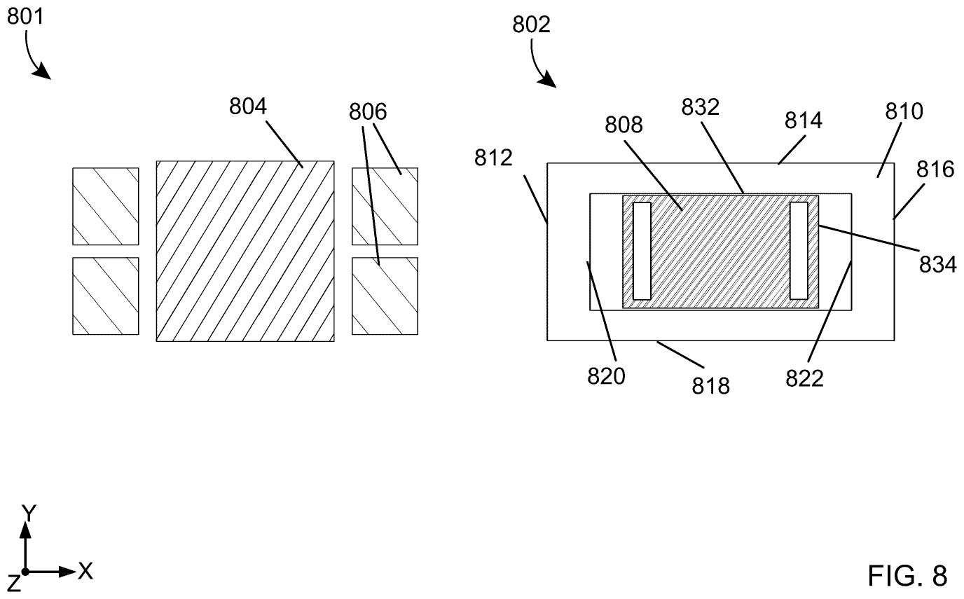

FIGS. 7-8 show schematic plan views in the X-Y plane of a plurality of semiconductor devices and example cooling apparatuses corresponding to the semiconductor devices, in accordance with embodiments of the present disclosure. FIG. 7 shows plan views of an example device layout 701 and a corresponding cooling apparatus 702. The device layout 701 includes a first die 704 and a plurality of second dies 706. Here, four second dies 706 are shown as two groups of second dies, each group disposed adjacent to opposite sides of the first die 704. At FIGS. 7-8, to illustrate the plan views in the X-Y plane, the spatially relative term “upper,” “lower,” “top,” or “bottom” is made with reference to the Y-axis relative to a structure to which the term refers, and the spatially relative term “left” or “right” is made with reference to the X-axis relative to a structure to which the term refers.

The cooling apparatus 702 includes a cold plate 708, a first heat sink 710, and a second heat sink 712. Here, the cooling apparatus 702 may be disposed on the devices as shown in the device layout 701. That is, the cold plate 708 is disposed at a position corresponding to the first die 704. A first heat sink 710 is disposed at a position corresponding to a first group of the second dies 706 having at least two dies, and a second heat sink 712 is disposed at a position corresponding to a second group of second dies 706 having at least two dies. Here, the first heat sink 710 may be attached to the two dies in the first group of second dies 706, and the second heat sink 712 may be attached to the two dies in the second group of second dies 706. Referring to FIG. 6, the first die 704 may be analogous with the first die 622. Each group of second dies 706 may be respectively analogous with the second dies 614, 616. The cold plate 708 may be analogous with the cold plate 621. The first and second heat sinks may be respectively analogous with the heat sinks attached to the second dies, such as the heat sinks 604, 605. In some embodiments, each of the second dies 706 has one or more respective heat sinks attached thereto. A plurality of heat sinks may be attached to each second die 706. That is, each second die have a heat spreader disposed on the second die and a heat sink disposed on the heat spreader as described with respect to FIG. 6. The cold plate 708 includes openings 714, 716 respectively corresponding to an inlet, such as the inlet portion 624, and an outlet, such as the outlet portion 628.

The lateral area of the cold plate 708 in the X-Y plane may be comparable with the lateral area of the first die 704 in the X-Y plane. In some embodiments, the lateral area of the cold plate 708 may be less than the lateral area of the first die 704. That is, the sides of the cold plate 708 in the X-Y plane, such as an upper X-direction side 726 extending along the X-axis and a right Y-direction side 728 extending along the Y-axis, may have a length within a range relative to a corresponding side of the first die 704, such as in a range of about 80% of the first die 704, or within about 90% of the first die 704, or within about 95% of the first die 704. In some embodiments, the lateral area of the cold plate 708 is about the same as or greater than the lateral area of the first die 704. As previously discussed with respect to FIG. 6, the cold plate 708 may be spaced apart from the heat sinks 710, 712, defining a gap between the upper X-direction side 726 of the cold plate 708 and a lower X-direction side 724 of the first heat sink 710.

In some embodiments, a plurality of second dies is disposed adjacent to a periphery of an integrated cooling assembly. A first heat sink and a second heat sink may be attached to different respective dies of the plurality of second dies. Here, an upper X-direction side group of second dies 706 is disposed adjacent to an upper X-direction side of the first die 704 extending along the X-axis, and a lower X-direction side group of second dies 706 is disposed adjacent to a lower X-direction side of the first die 704 extending along the X-axis. The second dies 706 in each group are disposed successively along the X-direction. At the device layout 701, each group of second dies have an overall X-direction length that is less than the X-direction length of the first die 704. Here, the first die 704 has a Y-direction length that is greater than each group of second dies 706. The first heat sink 710 is attached to the upper X-direction side group of the second dies 706 and is disposed adjacent to the upper X-direction side 726 of the cold plate 708. The second heat sink 712 is attached to the lower X-direction side group of the second dies 706 and is disposed adjacent to a lower X-direction side of the cold plate 708. That is, the first heat sink 710 and the second heat sink 712 are attached to different respective dies of the second dies 706, the different respective dies of the second dies 706 being disposed adjacent to opposite sides of the first die 704. Here, an integrated cooling assembly, including the cold plate 708 attached to the first die 704, is disposed between the first heat sink 710 and the second heat sink 712.

In some embodiments, a heat sink, such as the first heat sink 710, is attached to two or more dies. The following paragraph is made with reference to the first heat sink 710. It is noted and appreciated that the description with reference to the first heat sink 710 may apply to the second heat sink 712 with the spatially relative terms adjusted accordingly. Here, the first heat sink 710 may be attached to both dies of the upper X-direction side group of second dies 706. The first heat sink 710 includes a plurality of sides, such as a first Y-direction side 720, an upper X-direction side 722, and a lower X-direction side 724. The first heat sink 710 may have a lateral area that is comparable to the overall lateral area occupied by the upper X-direction side group of second dies 706. That is, the first Y-direction side 720 has a length that is comparable to the overall Y-direction length of the upper X-direction side group of second dies 706 from a bottom sidewall of a bottommost die in the upper X-direction side group of second dies 706 along the Y-axis to a top sidewall of a topmost die in the upper X-direction side group of second dies 706 along the Y-axis. In some embodiments, the first Y-direction side 720 and the overall Y-direction length of the upper X-direction side group of second dies 706 are about the same length. Analogously, the upper X-direction side 722 and the lower X-direction side 724 of the first heat sink 710 may be comparable to an overall X-direction length of the upper X-direction side group of second dies 706 from a left sidewall of a leftmost die in the upper X-direction side group of second dies 706 along the X-axis to a right sidewall of a rightmost die in the upper X-direction side group of second dies 706 along the X-axis. For the device layout 701, the overall X-direction length of the upper X-direction side group of second dies 706 is the same as the X-direction length of one second die 706.

FIG. 8 shows schematic plan views of an example device layout 801 and a corresponding cooling apparatus 802. Here, the cooling apparatus 802 may be disposed on the devices as shown in the device layout 801. The device layout 801 includes a first die 804 and a plurality of second dies 806. Four second dies 806 are shown as two groups of second dies, each group disposed adjacent to opposite sides of the first die 804. Here, the second dies 806 in each group are disposed successively along the Y-direction. The cooling apparatus 802 includes a cold plate 808 and a heat sink 810.

The lateral area of the cold plate 808 in the X-Y plane may be comparable to the lateral area of the first die 804 in the X-Y plane. Here, the lateral area of the cold plate 808 may be less than the lateral area of the first die 804. That is, an upper X-direction side 832 of the cold plate 808 extending along the X-axis may have a length that is comparable to the side of the first die 804 corresponding to the upper X-direction side 832 of the cold plate 808, and a right Y-direction side 834 of the cold plate 808 extending along the Y-axis may have a length that is less than the side of the first die 804 corresponding to the right Y-direction side 834 of the cold plate 808. The cold plate 808 may be disposed on the first die 804 to be in thermal contact with at least a portion of the die backside. In some embodiments, the lateral area of the cold plate 808 may be about the same as or greater than the lateral area of the first die 804.

In some embodiments, a plurality of second dies is disposed adjacent to a periphery of an integrated cooling assembly. A single heat sink may be attached to the plurality of second dies and disposed adjacent to the periphery of the integrated cooling assembly. Here, the heat sink 810 is a single heat sink that is attached to the plurality of second dies 806 and disposed adjacent to a periphery of the cold plate 808. The heat sink 810 may be a single contiguous heat sink or an integrated assembly of heat sink sections. Here, the heat sink 810 includes a left Y-direction portion 812 extending along the Y-axis, an upper X-direction portion 814 extending along the X-axis, a right Y-direction portion 816 extending along the Y-axis, and a lower X-direction portion 818 extending along the X-axis. In some embodiments, the heat sink 810 has a cross section analogous with the heat sinks 604, 605 or the heat sinks 634, 635. That is, the heat sink 604 disposed adjacent to a left sidewall of the integrated cooling assembly 620 may correspond to the left Y-direction portion 812, and the heat sink 605 disposed adjacent to a right sidewall of the integrated cooling assembly 620 may correspond to the right Y-direction portion 816. Here, the left Y-direction portion 812 is disposed on a first group of the second dies 806 adjacent to a left side of the first die 804, and the right Y-direction portion 816 is disposed on a second group of the second dies 806 adjacent to a right side of the first die 804. The left and right Y-direction portions 812, 816 may be attached to their respective group of second dies 806. Here, the upper X-direction portion 814 is disposed on an upper left die of the first group of second dies 806 along the Y-axis and an upper right die of the second group of second dies 806 along the Y-axis, extending over a first portion of the first die 804. The first portion of the first die 804 may include the side of the first die 804 corresponding to the upper X-direction side 832 of the cold plate 808. The lower X-direction portion 818 is disposed on a lower left die of the first group of second dies 806 and a lower right die of the second group of second dies 806, extending over a second portion of the first die 804. The second portion of the first die 804 may include the side of the first die 804 corresponding to a lower X-direction side of the cold plate 808. The upper and lower X-direction portions 814, 818 may be attached to their respective second dies.

In some embodiments, the upper and lower X-direction portions 814, 818 may be disposed on their respective portions of the first die 804. In some embodiments, the upper and lower X-direction portions 814, 818 are spaced apart from their respective portions of the first die. The heat sink 810 may be attached to the second dies 806 without extending over the first die 804. That is, the upper and lower X-direction portions 814, 818 may extend between the first and second groups of dies outside a periphery of the first die 804 in the X-Y plane.

The cold plate 808 may be spaced apart from the heat sink 810. Here, the left Y-direction portion 812 includes an inner left Y-direction side 820 that is spaced apart from a corresponding left side of the cold plate 808 by a first gap, such as the gap 642 or gap 644. The right Y-direction portion 816 includes an inner right Y-direction side 822 that is spaced apart from a corresponding right side of the cold plate 808 by a second gap. That is, the second gap is disposed between the right Y-direction side 834 of the cold plate 808 and the inner right Y-direction side 822 of the right Y-direction portion 816. The left Y-direction portion 812 and the cold plate 808 may be spaced apart by about the same distance along the X-axis as between the right Y-direction portion 816 and the cold plate 808 along the X-axis. In some embodiments, the left Y-direction portion 812 and the cold plate 808 may be spaced apart by a different distance than between the right Y-direction portion 816 and the cold plate 808. Here, the upper X-direction portion 814 may be spaced apart from the upper X-direction side 832 of the cold plate 808 by a different distance along the Y-axis than between the right Y-direction side 834 of the cold plate 808 and the inner right Y-direction side 822 along the X-axis. In some embodiments, the upper X-direction portion 814 and the cold plate 808 may be spaced apart by about the same distance along the Y-axis as between the right Y-direction side 834 of the cold plate 808 and the inner right Y-direction side 822 along the X-axis.

It is noted that the heat sink 810 may comprise fins or other extended portions (not shown) having a cross-section such as the vertical fins 606 or the lateral fins 636. In some embodiments, the heat sink 810 may be a flat heat spreader that does not include fins or other extended portions. In some embodiments, lateral fins of a portion of the heat sink 810 may be oriented along a different direction than lateral fins of another portion of the heat sink 810. That is, in embodiments where the heat sink 810 includes the lateral fins 636, the left and right Y-direction portions 812, 816 may have the lateral fins extending in the X-direction away from a heat sink base and/or respective sidewalls of an integrated cooling assembly including the cold plate 808 extending along the Z-axis, and the upper and lower X-direction portions 814, 818 may have the lateral fins extending in the Y-direction away from the heat sink base and/or respective sidewalls of the integrated cooling assembly including the cold plate 808 extending along the Z-axis. The fins or extended portions of the heat sink 810 may be arranged to provide an interface between a gaseous coolant and the heat sink 810.

The device layouts 701, 801 are intended to be illustrative and non-limiting. It is contemplated that any device layout of two or more dies disposed on a substrate, such as in an MCM or other multi-device arrangement, may be included with a corresponding cooling apparatus within the principles set forth in the present disclosure. That is, a device layout may include any number of first dies, typically arranged within a central region, and any number of second dies adjacent to the first die(s), typically arranged on the substrate within peripheral regions around the central region.

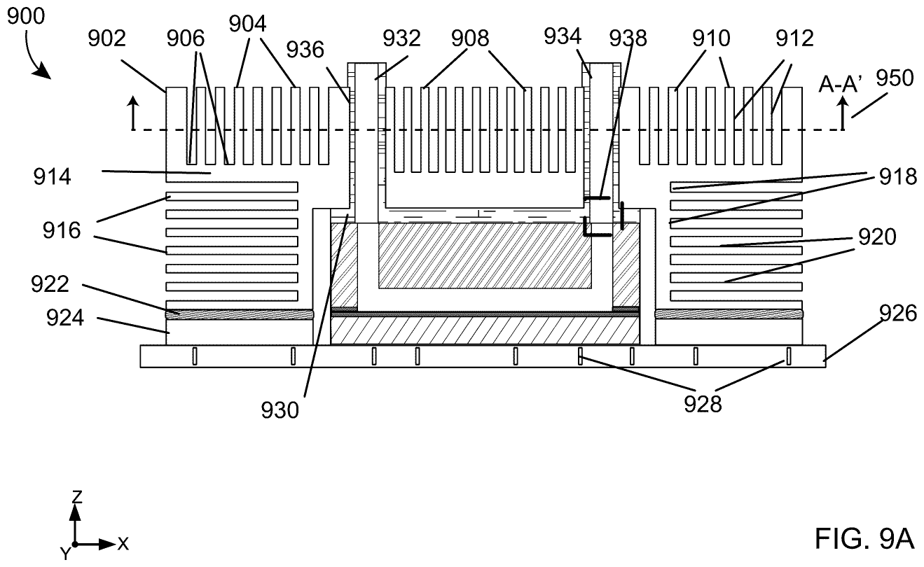

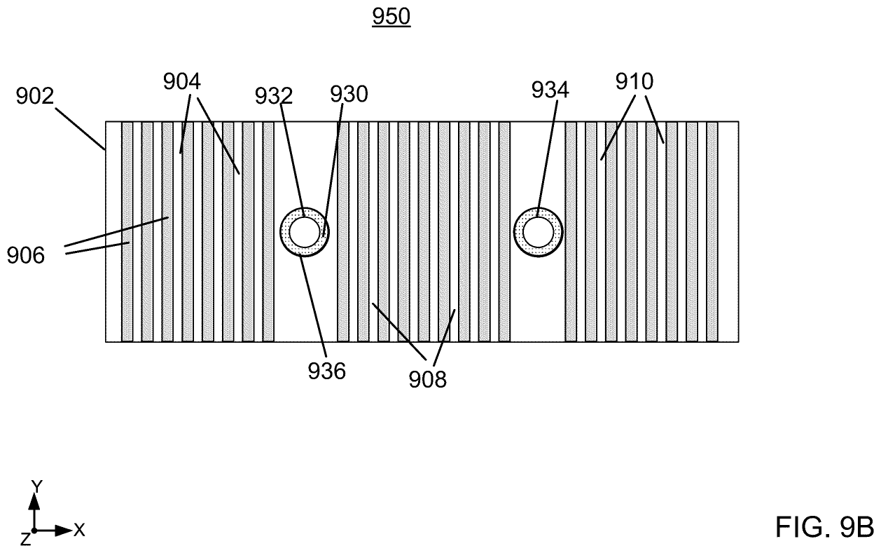

FIG. 9 shows schematic sectional views of a cooling apparatus 900 including an integrated cooling assembly and a single heat sink 902 comprising an upper heat sink portion 950 disposed over the integrated cooling assembly. Here, the heat sink 902 is arranged for a gaseous coolant. FIG. 9A shows a sectional view in the X-Z plane of the cooling apparatus 900. FIG. 9B shows a sectional view of the upper heat sink portion 950 in the X-Y plane as taken along line A-A′ of FIG. 9A. The cooling apparatus 900 includes a substrate, such as an interposer 926 including one or more conductive features such as interconnects, pads, through silicon vias (TSVs), conductive lines, wiring, etc. (here labeled interconnections 928). The integrated cooling assembly includes a cold plate having at least a portion attached to a backside of a first die. The first die is attached to the interposer 926. The first die may be attached using solder, conductive bumps such as microbumps, direct dielectric bonding, hybrid bonding, etc. In some embodiments, the first die is directly bonded to the interposer 926. A plurality of second dies, such as a left second die 924, is attached to the interposer 926. In some embodiments, the plurality of second dies is directly bonded to the interposer 926. The first die is communicatively coupled to each second die of a plurality of second dies. Here, the first die is communicatively coupled to each of the second dies, such as the left second die 924, through the interconnections 928 via the interposer 926.

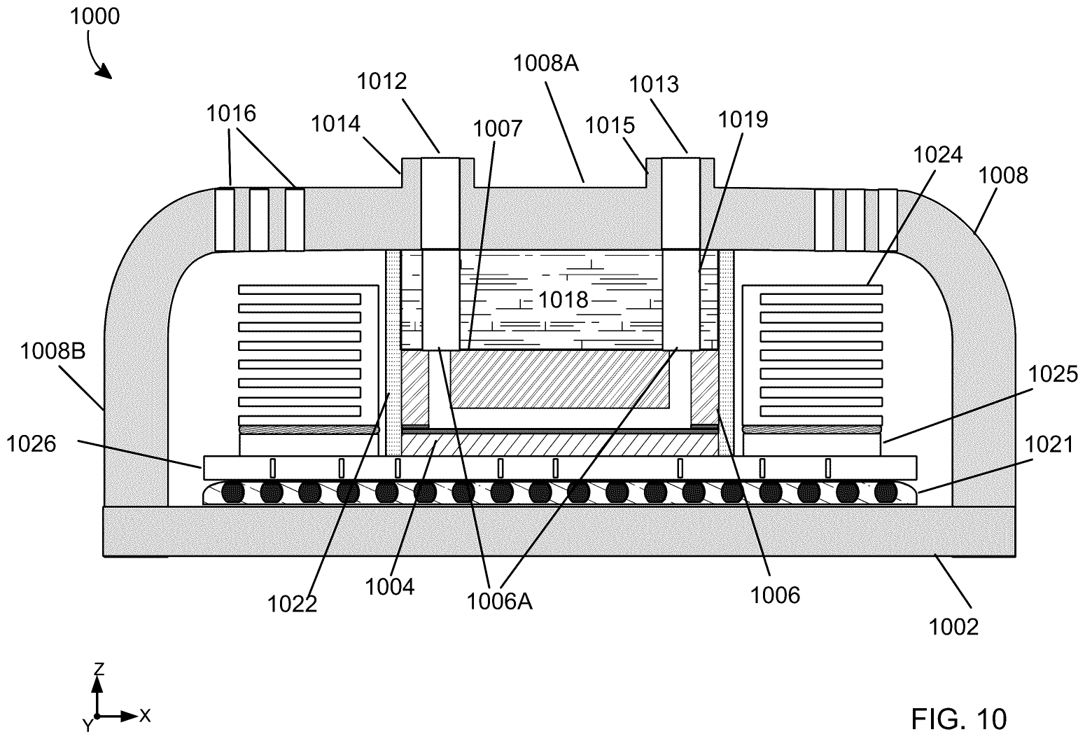

In some embodiments, a manifold 930 is disposed between the integrated cooling assembly and the heat sink 902. The manifold 930 may be arranged for delivering a coolant fluid to the integrated cooling assembly. Here, the manifold 930 is attached to a side of the cold plate of the integrated cooling assembly. The manifold 930 includes one or more coolant channels, such as a manifold inlet channel 932 and a manifold outlet channel 934 in fluid communication with at least one fluid channel of the integrated cooling assembly, such as the coolant chamber volume 210, such as the lateral channel portion 626. That is, a first coolant line may be attached to the manifold inlet channel 932 that couples an inlet of the cold plate, such as the inlet portion 624, to a coolant source, and a second coolant line may be attached to the manifold outlet channel 934 that couples an outlet of the cold plate, such as the outlet portion 628, to the coolant source. Sidewalls of the integrated cooling assembly extend vertically along the Z-direction away from the interposer 926. In some embodiments, a sealing material layer is disposed between the integrated cooling assembly, or a portion thereof, and one or more heat sinks, such as the heat sink 902 or the heat sinks 604, 605, 634, and 635 (described with respect to FIG. 10). That is, the sealing material layer may be disposed between a sidewall of the integrated cooling assembly and the one or more heat sinks. The manifold 930 may be capable of delivering coolant fluid through the sealing material layer disposed between the integrated cooling assembly and the heat sink 902. Referring to FIG. 3, the manifold channels 932, 934 may be in registration and fluid communication with openings, such as an opening 938 corresponding to the opening 222A, disposed through the sealing material layer 222. Referring to FIG. 9B, each of the manifold channels 932, 934 is disposed through a respective gap in the heat sink portion 950. In some embodiments, the manifold comprises a thermally insulating material such as a polymer or epoxy, such as plastic. Here, a thermal insulator is disposed within the respective gap between each of the manifold channels 932, 934, such as between an inner heat sink sidewall 936 and the manifold channel 932. In some embodiments, a manifold channel is spaced apart from an inner heat sink sidewall. That is, the manifold channel may be insulated from the inner heat sink sidewall by an air gap. Here, the manifold channels 932, 934 and their respective gaps are circular in the X-Y plane. The manifold channel 932 is concentric with the inner heat sink sidewall 936. It is contemplated that the manifold channels 932, 934 may have any cross-sectional geometry, such as rectangular, circular, elliptical, polygonal such as hexagonal, etc., and the inner heat sink sidewall 936 may be conformed accordingly or shaped differently from the manifold channels 932, 934. Referring to FIG. 3, the manifold channels 932, 934 may be in fluid communication with openings of a package cover in a device package, such as the inlet and outlet openings 212 of the package cover 208 (described with respect to FIG. 10).

The heat sink 902 includes a first heat sink portion, such as a left heat sink portion with lateral fins 916 extending towards the left in the negative X-direction orthogonal to and away from a left sidewall of the integrated cooling assembly, and a second heat sink portion, such as a right heat sink portion with lateral fins extending towards the right in the positive X-direction orthogonal to and away from a right sidewall of the integrated cooling assembly. The left and right heat sink portions include respective heat sink bases, such as a right heat sink base 918. The lateral fins include respective lateral fin sidewalls, such as right lateral fin sidewalls 920 extending away from the right heat sink base 918 along the X-axis. Two or more second dies of the plurality of second dies are disposed adjacent to different sides of the integrated cooling assembly. The heat sink 902 is attached to the second dies disposed adjacent to the different sides of the integrated cooling assembly. Here, the left heat sink portion of the heat sink 902 is attached to the second dies disposed adjacent to a left sidewall of the integrated cooling assembly using a TIM layer, such as the TIM layer 922 disposed between the left heat sink portion and the left second die 924. The upper heat sink portion 950 shares a side with each of the left and right heat sink portions, such as a sidewall portion 914 between the left heat sink portion and the upper heat sink portion 950. Here, the upper heat sink portion 950 includes a heat sink base 906 at the sidewall portion 914.

Referring to FIG. 9B, the upper heat sink portion 950 further includes left vertical fins 904 disposed over the left heat sink portion, middle vertical fins 908 disposed over the integrated cooling assembly, and right vertical fins 910 disposed over the right heat sink portion. Each of the vertical fins 904, 908, 910 include respective heat sink bases, such as the heat sink base 906 for the vertical fins 904, and respective vertical fin sidewalls, such as the right vertical fin sidewalls 912. The vertical fins 904, 908, 910 extend vertically in the positive Z-direction away from their respective heat sink bases. Referring to FIG. 9B, the upper heat sink portion 950 includes plate-type vertical fins that extend along the Y-direction. Here, the plate-type vertical fins include vertical fin sidewalls having a substantially planar surface. It is contemplated that the upper heat sink portion 950 may have other fin geometries, such as pin-type fins, as previously discussed with respect to FIG. 6, or no fins, such as a flat heat spreader.

As discussed in previous paragraphs, in some embodiments, the heat sink 902 may not include vertical fins and/or lateral fins at one or more heat sink portions. That is, one or more of the left, middle heat sink portion, and right heat sink portions of the heat sink 902 may be substantially planar without fins. In one embodiment, the heat sink 902 includes a heat spreader that extends upwardly from the second die 924 adjacent to a left side of the integrated cooling assembly along the Z-direction orthogonal to the interposer 926, extends over the integrated cooling assembly, such as along the X-direction parallel to the cold plate backside of the integrated cooling assembly, and extending upwardly from a second die adjacent to a right side of the integrated cooling assembly along the Z-direction orthogonal to the interposer 926.

FIG. 10 shows a schematic sectional view in the X-Z plane of an example device package 1000 including a cooling apparatus attached to a package substrate 1002, the cooling apparatus having an integrated cooling assembly arranged for a liquid coolant and a plurality of heat sinks 1024 arranged for a gaseous coolant. The integrated cooling assembly includes a cold plate 1006 attached to a first die 1004. The cold plate 1006 may be directly bonded to the first die 1004. The plurality of heat sinks 1024 are attached to corresponding second dies, such as the second die 1025.

Here, the device package 1000 includes a package cover 1008 having sidewall portions 1008B and a lateral portion 1008A that extends over the cooling apparatus. The lateral portion 1008A spans and connects the sidewall portions 1008B. Here, the sidewall portions 1008B extend upwardly from a peripheral portion of the package substrate 1002. The package cover 1002 further includes an inlet opening 1012 and an outlet opening 1013. The package cover 1002 may include protruding features 1014 that surrounds the inlet opening 1012 and protruding features 1015 that surrounds the outlet opening 1013, where the protruding features 1014, 1015 extend upwardly from the lateral portion 1008A. In some embodiments, coolant lines may be attached to the device package 1000 using connector features formed in the package cover 1008, such as in the sidewalls of the openings 1012, 1013, and/or the protruding features 1014, 1015. The device package 1000 further includes openings for forced or natural convection, such as airflow openings 1016. Here, the airflow openings 1016 are disposed over the heat sinks 1024 through the lateral portion 1008A, extending vertically along the Z-axis. It is contemplated that the airflow openings 1016 may be disposed at any portion of the package cover 1008 based on the arrangement of the heat sinks 1024, such as at the sidewall portions 1008B or at a portion between the lateral portion 1008A and the sidewall portions 1008B.

The integrated cooling assembly is in fluid communication with the inlet and outlet openings 1012, 1013 of the package cover 1008. Here, the inlet opening 1012 and the outlet opening 1013 are fluidly coupled to respective openings 1006A through manifold channels 1019 of a manifold 1018. The manifold 1018 is disposed between the integrated cooling assembly and the package cover 1008. In some embodiments, the manifold 1018 is attached to the integrated cooling assembly. Here, the manifold 1018 is disposed on a side 1007 of the cold plate 1006, the side 1007 facing towards the lateral portion 1008A. The manifold 1018 may comprise a rigid material, such as an epoxy, a polymer, or another supporting material that is impermeable to a coolant fluid delivered through the inlet and outlet openings 1012, 1013. In some embodiments, the manifold 1018 comprises a semiconductor material, such as structural silicon.

Here, the cooling apparatus is attached to an interposer 1026. The interposer 1026 is disposed on an underfill layer 1021 between the interposer 1026 and the package substrate 1002. The first die 1004 and the plurality of second dies, such as the second die 1025, are attached to the interposer 1026. The first die 1004 and the plurality of second dies may be bonded to the interposer 1026. Here, the first die 1004 is communicatively coupled to each of the second dies via the interposer 1026. The cooling apparatus includes a sealing material layer 1022 that forms a coolant fluid impermeable barrier for preventing coolant fluid from reaching an active side of the first die 1004. That is, the sealing material layer 1022 may encapsulate the integrated cooling assembly or a portion thereof. The sealing material layer 1022 is disposed between the integrated cooling assembly and the heat sinks 1024. Here, the sealing material layer 1022 does not encapsulate the heat sinks 1024, leaving the fins or other extended portions of the heat sinks 1024 exposed for a gaseous coolant. That is, the sealing material layer 1022 is spaced apart from the heat sinks 1024 by a gap. In some embodiments, the sealing material layer 1022 surrounds and encapsulates at least a portion of the plurality of second dies, such as around the sidewalls of the second die 1025, and does not encapsulate the heat sinks 1024. In some embodiments, the sealing material layer 1022 provides structural support for the integrated cooling assembly and/or the manifold 1018. As shown at FIG. 10, the sealing material layer 1022 may extend vertically in the Z-direction orthogonal to the interposer 1026 along the sidewalls of the integrated cooling assembly, or portions thereof such as the cold plate 1006, and/or the manifold 1018. In some embodiments, the sealing material layer 1022 extends vertically along the sidewalls of the integrated cooling assembly starting from the interposer 1026 and ending at the side 1007 of the cold plate 1006. In some embodiments, a thermal interface material is deposited between one or more of the plurality of second dies, such as the second die 1025, and the package cover 1008. That is, the second die 1025 and the package cover 1008 may be in thermal contact. In some embodiments, at least one of the second dies comprises a die stack, such that a topmost die of this die stack is in thermal contact with the package cover 1008 via a thermal interface material disposed between the topmost die and the package cover 1008. In some embodiments, a thickness of the topmost die of the die stack in a direction perpendicular to the die backside, here along the Z-direction, is thicker than another die of the die stack in the same direction. The thickness of the topmost die along the Z-direction may be greater than all the other dies of the die stack in the same direction. In some embodiments, the package cover 1008 comprises a heat spreader, such as at the lateral portion 1008A. The package cover 1008, or a portion thereof, may comprise a thermally conductive material. That is, the package cover may comprise a metal, such as copper, aluminum, etc.

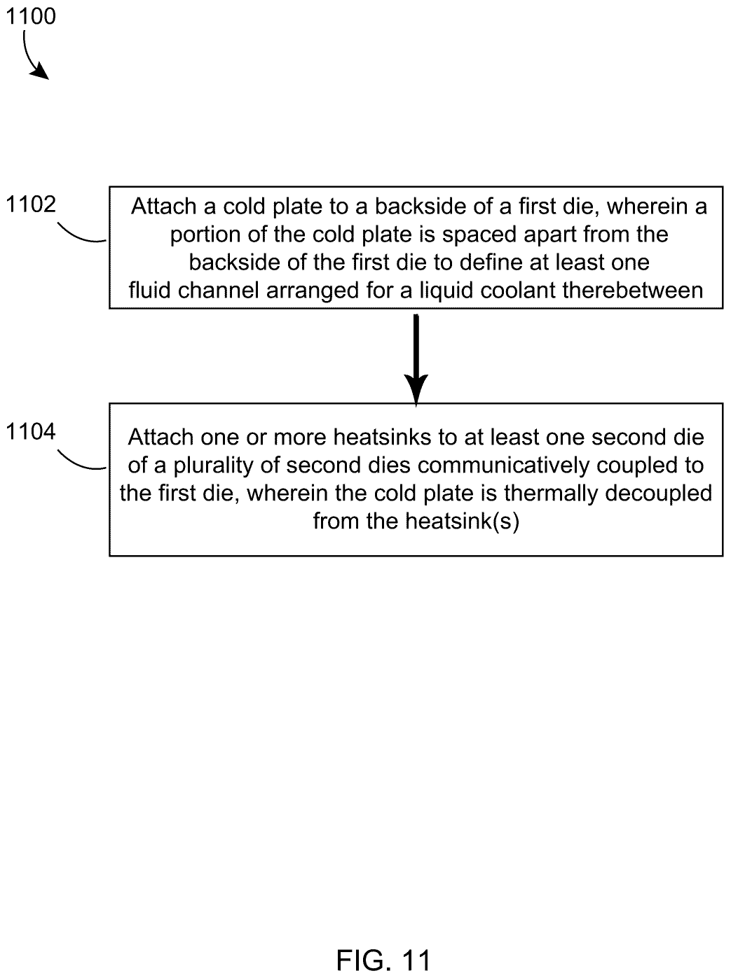

FIG. 11 shows a flow diagram for an example process 1100 of manufacturing a cooling apparatus, in accordance with embodiments of the present disclosure. The cooling apparatus comprises an integrated cooling assembly, the integrated cooling assembly comprising a first die and a cold plate, a plurality of second dies communicatively coupled to the first die, and one or more heat sinks. The process 1100 may be applied during manufacture for any of the cooling apparatuses as described herein, such as the cooling apparatuses 601, 602, 702, 802, 900.

At block 1102, the cold plate is attached to the first die. That is, at least a first portion of the cold plate is attached to a backside of the first die. A second portion of the cold plate is spaced apart from a side of the first die to define at least one first fluid channel arranged for a liquid coolant between the side of the cold plate and the side of the first die. In some embodiments, attaching the cold plate to the first die includes directly bonding at least the first portion of the cold plate to the backside of the first die. That is, attaching the cold plate to the first die may comprise direct dielectric bonding or direct hybrid bonding.

At block 1104, the one or more heat sinks are attached to at least one second die of the plurality of second dies. The cold plate is thermally decoupled from the one or more heat sinks. That is, the cold plate corresponds to a first heat transfer path and the one or more heat sinks correspond to a second heat transfer path that is different from the first heat transfer path such that heat is not transferred between the cold plate and each of the one or more heat sinks. In some embodiments, the one or more heat sinks are arranged for a gaseous coolant. In some embodiments, the one or more heat sinks comprise a first heat sink and a second heat sink. Attaching the one or more heat sinks to the at least one second die comprises attaching the first heat sink and the second heat sink to different respective dies of the plurality of second dies. The integrated cooling assembly may be disposed between the first heat sink and the second heat sink. In some embodiments, attaching the one or more heat sinks to the at least one second die comprises disposing a TIM layer on the at least one second die and attaching a heat sink of the one or more heat sinks to the at least one second die using the TIM layer.

In some embodiments, two or more second dies of the plurality of second dies are disposed adjacent to different sides of the integrated cooling assembly. The method may further comprise attaching a manifold to the integrated cooling assembly, the manifold comprising one or more coolant channels in fluid communication with the at least one fluid channel, and attaching a heat sink of the one or more heat sinks to the two or more second dies. The heat sink may comprise a heat sink portion disposed over the integrated cooling assembly. The one or more coolant channels may be disposed through respective gaps in the heat sink portion.

The embodiments discussed above are intended to be illustrative and not limiting. One skilled in the art would appreciate that individual aspects of the cooling assemblies, device packages, and methods discussed herein may be omitted, modified, combined, and/or rearranged without departing from the scope of the disclosure.

1. A cooling apparatus comprising:
an integrated cooling assembly comprising:
a first die; and
a cold plate having first and second portions, wherein the first portion is directly bonded to a backside of the first die, and wherein the second portion is spaced apart from the backside of the first die to define at least one fluid channel arranged for a liquid coolant between the second portion of the cold plate and the backside of the first die;
a plurality of second dies communicatively coupled to the first die; and
one or more heat sinks attached to at least one second die of the plurality of second dies, wherein the cold plate is thermally decoupled from the one or more heat sinks.

2. The cooling apparatus of claim 1, wherein the at least one fluid channel has at least one inlet and at least one outlet defined by the cold plate.

3. The cooling apparatus of claim 1, wherein the one or more heat sinks are arranged for a gaseous coolant.

4. The cooling apparatus of claim 1, wherein the one or more heat sinks comprise a first heat sink and a second heat sink that are attached to different respective dies of the plurality of second dies, and wherein the integrated cooling assembly is disposed between the first heat sink and the second heat sink.

5. (canceled)

6. The cooling apparatus of claim 1, wherein the one or more heat sinks comprise fins, wherein the one or more heat sinks are disposed over the at least one second die, and wherein the fins extend vertically away from the at least one second die.

7. The cooling apparatus of claim 1, wherein the one or more heat sinks comprise fins, wherein the one or more heat sinks are disposed laterally adjacent to the integrated cooling assembly, and wherein the fins extend laterally away from the integrated cooling assembly.

8. The cooling apparatus of claim 1, wherein the plurality of second dies is disposed adjacent to a periphery of the integrated cooling assembly, and wherein the one or more heat sinks comprise a single heat sink attached to the plurality of second dies and disposed adjacent to the periphery of the integrated cooling assembly.

9. The cooling apparatus of claim 1, further comprising a manifold attached to the integrated cooling assembly, the manifold comprising one or more coolant channels in fluid communication with the at least one fluid channel.

10. The cooling apparatus of claim 9, wherein a heat sink of the one or more heat sinks comprises a heat sink portion disposed over the integrated cooling assembly, and wherein each coolant channel of the one or more coolant channels is disposed through a respective gap in the heat sink portion.

11. The cooling apparatus of claim 10, wherein two or more second dies of the plurality of second dies are disposed adjacent to different sides of the integrated cooling assembly, and wherein the heat sink is attached to the two or more second dies.

12-13. (canceled)

14. The cooling apparatus of claim 1, wherein the first portion of the cold plate is directly bonded to the backside of the first die through direct dielectric bonds formed between the cold plate and the first die.

15. The cooling apparatus of claim 1, wherein the first portion of the cold plate is directly bonded to the backside of the first die through direct hybrid bonds formed between the cold plate and the first die.

16-18. (canceled)

19. The cooling apparatus of claim 1, wherein the cold plate comprises:
a perimeter sidewall comprising the first portion of the cold plate;
a top portion comprising the second portion of the cold plate; and
a cavity divider comprising cavity sidewalls, wherein:
the perimeter sidewall extends downwardly from the top portion to the backside of the first die to define a perimeter of the cold plate;
the cavity divider extends downwardly from the top portion towards the backside of the first die; and
the cavity sidewalls, the perimeter sidewall, and the backside of the first die collectively define the at least one fluid channel therebetween.

20-21. (canceled)

22. A method for manufacturing a cooling apparatus comprising an integrated cooling assembly, the integrated cooling assembly comprising a first die and a cold plate, wherein the cooling apparatus further comprises a plurality of second dies communicatively coupled to the first die and one or more heat sinks, the method comprising:
directly bonding a first portion of the cold plate to a backside of the first die, wherein a second portion of the cold plate is spaced apart from the backside of the first die to define at least one fluid channel arranged for a liquid coolant between the second portion of the cold plate and the backside of the first die; and
attaching the one or more heat sinks to at least one second die of the plurality of second dies, wherein the cold plate is thermally decoupled from the one or more heat sinks.

23. The method of claim 22, wherein the at least one fluid channel has at least one inlet and at least one outlet defined by the cold plate.

24. The method of claim 22, wherein the one or more heat sinks are arranged for a gaseous coolant.

25. The method of claim 22, wherein directly bonding the cold plate to the backside of the first die comprises direct dielectric bonding.

26. The method of claim 22, wherein directly bonding the cold plate to the backside of the first die comprises direct hybrid bonding.

27. The method of claim 22, wherein the one or more heat sinks comprise a first heat sink and a second heat sink, and wherein attaching the one or more heat sinks to the at least one second die comprises:
attaching the first heat sink and the second heat sink to different respective dies of the plurality of second dies, wherein the integrated cooling assembly is disposed between the first heat sink and the second heat sink.

28. (canceled)

29. The method of claim 22, wherein two or more second dies of the plurality of second dies are disposed adjacent to different sides of the integrated cooling assembly, the method further comprising:
attaching a manifold to the integrated cooling assembly, the manifold comprising one or more coolant channels in fluid communication with the at least one fluid channel; and
attaching a heat sink of the one or more heat sinks to the two or more second dies, wherein the heat sink comprises a heat sink portion disposed over the integrated cooling assembly, the one or more coolant channels being disposed through respective gaps in the heat sink portion.

30. The method of claim 22, wherein the cold plate comprises a perimeter sidewall comprising the first portion of the cold plate, a top portion comprising the second portion of the cold plate, and a cavity divider comprising cavity sidewalls, and wherein directly bonding the first portion of the cold plate to the backside of the first die comprises:
directly bonding the perimeter sidewall to the backside of the first die, wherein:
the perimeter sidewall extends downwardly from the top portion to the backside of the first die to define a perimeter of the cold plate;
the cavity divider extends downwardly from the top portion towards the backside of the first die; and
the cavity sidewalls, the perimeter sidewall, and the backside of the first die collectively define the at least one fluid channel therebetween.
